(19) United States
(12) Patent Application Publication
(10) Pub. No.: US 2025/0366211 A1
(43) Pub. Date: Nov. 27, 2025

(54) INTEGRATED CIRCUIT (IC) DEVICE, IC LAYOUT, AND METHOD OF GENERATING IC LAYOUT

(71) Applicant: TAIWAN SEMICONDUCTOR MANUFACTURING COMPANY, LTD., Hsinchu (TW)

(72) Inventors: Shang-Wei FANG, Hsinchu (TW); Jiann-Tyng TZENG, Hsinchu (TW); Yi-Kan CHENG, Hsinchu (TW); Yen-Hung LIN, Hsinchu (TW); Sheng-Feng HUANG, Hsinchu (TW)

(21) Appl. No.: 19/292,235

(22) Filed: Aug. 6, 2025

Related U.S. Application Data
(63) Continuation of application No. 18/616,730, filed on Mar. 26, 2024.
(60) Provisional application No. 63/611,508, filed on Dec. 18, 2023.

(51) Int. Cl. H10D 89/10; G06F 30/392; H10D 30/43; H10D 30/67; H10D 62/10; H10D 84/83

(52) U.S. Cl. CPC H10D 89/10; G06F 30/392; H10D 30/43; H10D 30/6735; H10D 30/6757; H10D 62/121; H10D 84/83

(57) ABSTRACT

An IC device includes rows of semiconductor devices elongated along a first axis and arranged side-by-side along a second axis. The rows include first rows having a first height, and second rows having a second height smaller than the first height along the second axis. Each row includes first and second active regions of different conductivity types, and spaced from each other along the second axis. In one or more first rows, the first or second active region comprises a portion having a first width along the second axis, and a further portion having a reduced first width smaller than the first width. Alternatively or additionally, in one or more second rows, the first or second active region comprises a portion having a second width along the second axis, and a further portion having a reduced second width smaller than the second width.

### RELATED APPLICATION(S)

This application is a continuation application of U.S. patent application Ser. No. 18/616,730, filed Mar. 26, 2024, which claims the benefit of U.S. Provisional Application No. 63/611,508, filed Dec. 18, 2023. The above-referenced applications are herein incorporated by reference in their entireties.

### BACKGROUND

An integrated circuit (“IC”) device includes one or more semiconductor devices represented in an IC layout diagram (also referred to as “IC design layout diagram,” “layout diagram,” “IC layout,” or “layout”). A layout diagram is hierarchical and includes modules which carry out higher-level functions in accordance with the semiconductor device's design specifications. The modules are often built from a combination of cells, each of which represents one or more semiconductor structures configured to perform a specific function. Cells having pre-designed layout diagrams, sometimes known as standard cells, are stored in standard cell libraries (hereinafter “libraries” or “cell libraries” for simplicity) and accessible by various tools, such as electronic design automation (EDA) tools, to generate, optimize and verify designs for ICs. Power, performance and area (PPA) are design considerations for IC devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a block diagram of an IC device, in accordance with some embodiments.

FIG. 1B is a perspective view of a portion of an IC device, in accordance with some embodiments.

FIG. 1C is a cross-sectional view of the portion of the IC device of FIG. 1B, in accordance with some embodiments.

FIG. 2A is a schematic view of an IC layout of a circuit region of an IC device, in accordance with some embodiments.

FIG. 2B is a simplified schematic view of the IC layout of FIG. 2A, in accordance with some embodiments.

FIG. 2C includes schematic views of various cell row configurations in one or more IC layouts, in accordance with some embodiments.

FIG. 3 includes schematic views of various cells placeable in an IC layout, in accordance with some embodiments.

FIG. 4A is a schematic view of an IC layout of a circuit region of an IC device, in accordance with some embodiments.

FIG. 4B and FIG. 4C are schematic views of various cell row configurations in one or more IC layouts, in accordance with some embodiments.

FIG. 5A is a block diagram of an IC device, in accordance with some embodiments.

FIG. 5B and FIG. 5C are schematic views of IC layouts of various circuit regions of one or more IC devices, in accordance with some embodiments.

FIG. 6 is a schematic view of an IC layout of a circuit region of an IC device, in accordance with some embodiments.

FIG. 7A includes a schematic circuit diagram and a cross-sectional view of a circuit region of an IC device, in accordance with some embodiments.

FIG. 7B and FIG. 7C are schematic views at various layers of an IC layout of the circuit region of FIG. 7A, in accordance with some embodiments.

FIG. 7D includes a schematic circuit diagram and a cross-sectional view of a circuit region of an IC device, in accordance with some embodiments.

FIG. 7E and FIG. 7F are schematic views at various layers of an IC layout of the circuit region of FIG. 7D, in accordance with some embodiments.

FIG. 8A is a schematic circuit diagram of a circuit region of an IC device, in accordance with some embodiments.

FIG. 8B is a schematic view of an IC layout of the circuit region of FIG. 8A, in accordance with some embodiments.

FIG. 9A and FIG. 9B are schematic views of IC layouts of various circuit regions of one or more IC devices, in accordance with some embodiments.

FIG. 10 is a table showing routing features of various cells placeable in an IC layout, in accordance with some embodiments.

FIG. 11 and FIG. 12 are flowcharts of various methods, in accordance with some embodiments.

FIG. 13 is a block diagram of an electronic design automation (EDA) system in accordance with some embodiments.

FIG. 14 is a block diagram of an IC device manufacturing system, and an IC manufacturing flow associated therewith, in accordance with some embodiments.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, merely examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Source/drain(s) may refer to a source or a drain, individually or collectively dependent upon the context.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, cells of different cell heights are read from one or more cell libraries, and placed in an IC layout, e.g., by an Automated Placement and Routing (APR) tool or system. Cells with cell heights greater than a unit cell height of a unit cell are sometimes referred to as tall cells, and are configured to improve (i.e., increase) performance or speed in one or more regions of IC devices manufactured in accordance with the IC layout. Cells with cell heights smaller than the unit cell height are sometimes referred to as short cells, and are configured to improve (i.e., reduce) power consumption and/or chip area (hereinafter referred to as “power and area”) in one or more further regions of the manufactured IC devices. In at least one embodiment, the IC layout further comprises unit cells. In some embodiments, active regions of neighboring cells are merged to configure a merged cell with improved performance or speed. In at least one embodiment, active region widths of one or more short cells, unit cells and/or tall cells are reduced to improve power and area. As a result, it is possible in one or more embodiments to optimize and/or customize the IC layout to improve speed in one or more regions while improving power and area in one or more further regions, in accordance with purposes and/or applications to be performed by IC devices manufactured based on the IC layout. These are improvements over other approaches where all cells in an IC layout have the same cell height. Further features in accordance with various embodiments and corresponding advantages are also described herein.

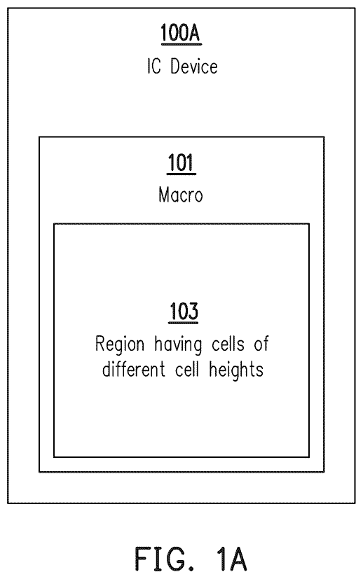

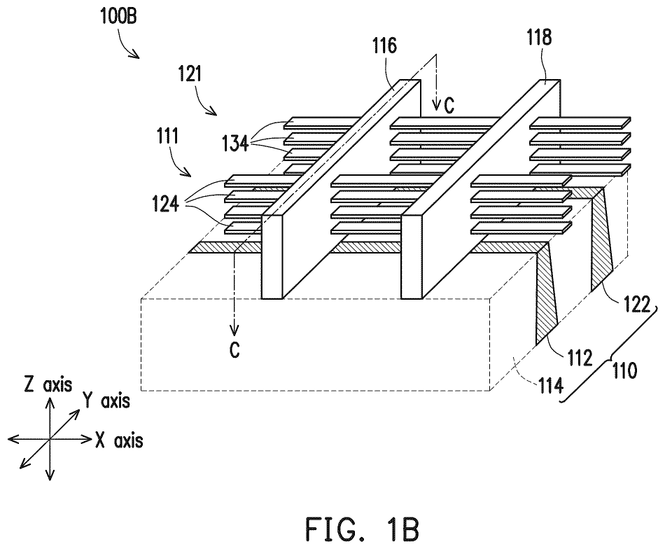

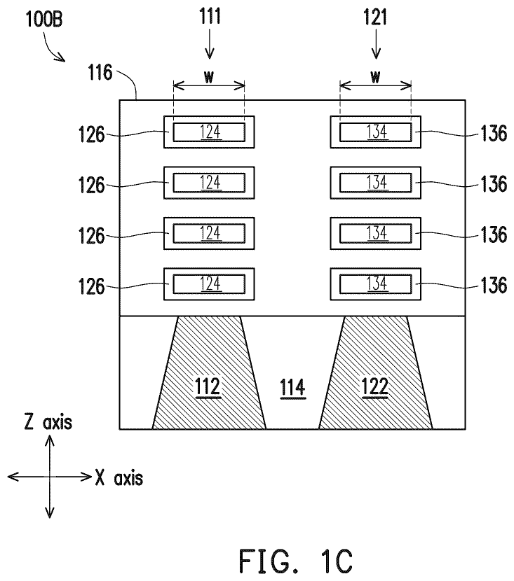

FIG. 1A is a block diagram of an IC device 100A, in accordance with some embodiments.

In FIG. 1A, the IC device 100A comprises, among other things, a macro 101. In some embodiments, the macro 101 comprises one or more of a memory, a power grid, a cell or cells, an inverter, a latch, a buffer and/or any other type of circuit arrangement that may be represented digitally in a cell library. In some embodiments, the macro 101 is understood in the context of an analogy to the architectural hierarchy of modular programming in which subroutines/procedures are called by a main program (or by other subroutines) to carry out a given computational function. In this context, the IC device 100A uses the macro 101 to perform one or more given functions. Accordingly, in this context and in terms of architectural hierarchy, the IC device 100A is analogous to the main program and the macro 101 is analogous to subroutines/procedures. In some embodiments, the macro 101 is a soft macro. In some embodiments, the macro 101 is a hard macro. In some embodiments, the macro 101 is a soft macro which is described digitally in register-transfer level (RTL) code. In some embodiments, synthesis, placement and routing have yet to have been performed on the macro 101 such that the soft macro can be synthesized, placed and routed for a variety of process nodes. In some embodiments, the macro 101 is a hard macro which is described digitally in a binary file format (e.g., Graphic Database System II (GDSII) stream format), where the binary file format represents planar geometric shapes, text labels, other information and the like of one or more layout-diagrams of the macro 101 in hierarchical form. In some embodiments, synthesis, placement and routing have been performed on the macro 101 such that the hard macro is specific to a particular process node.

The macro 101 includes a region 103, which comprises cells with different cell heights as described herein. In some embodiments, the region 103 comprises a substrate having circuitry formed thereon, in a front-end-of-line (FEOL) fabrication. Furthermore, above and/or below the substrate, the region 103 comprises various metal layers that are stacked over and/or under insulating layers in a back-end-of-line (BEOL) fabrication. The BEOL provides routing for circuitry of the IC device 100A, including the macro 101 and the region 103.

FIG. 1B is a perspective view of a portion of an IC device 100B, in accordance with some embodiments. In at least one embodiment, the IC device 100B corresponds on the IC device 100A.

The IC device 100B comprises a substrate 110 over which a plurality of semiconductor devices is formed. Two semiconductor devices 111, 121 of the IC device 100B are designated in FIG. 1B. In the example configuration in FIG. 1B, the semiconductor devices 111, 121 comprise nanosheet field-effect transistors (FETs), sometimes referred to as nanosheet devices. Nanosheet devices are examples of gate-all-around (GAA) devices. Other GAA configurations, such as nanowire FETs, sometimes referred to as nanowire devices, are within the scopes of various embodiments.

The substrate 110 comprises a substrate portion 112 corresponding to the semiconductor device 111, a substrate portion 122 corresponding to the semiconductor device 121, and an isolation region 114 between and around the substrate portions 112, 122. The substrate portions 112, 122 extend, or are elongated, along an X axis. In some embodiments, the substrate portions 112, 122 are portions of a same wafer (not shown). The wafer has been partially removed during manufacture of the IC device 100B, with the substrate portions 112, 122 remaining. In some embodiments, the wafer is a semiconductor substrate, such as a bulk semiconductor, a semiconductor-on-insulator (SOI) substrate, or the like, which is doped (e.g., with a P-type or an N-type dopant) or undoped. Generally, an SOI substrate comprises a layer of a semiconductor material formed on an insulator layer. Example materials of the insulator layer include, but are not limited to, a buried oxide (BOX) layer, a silicon oxide layer, or the like. The insulator layer is provided on a silicon substrate, a glass substrate, a multi-layered substrate, or a gradient substrate. In some embodiments, the substrate portions 112, 122 include a semiconductor material, including, but not limited to, an elemental semiconductor including silicon or germanium in crystal, polycrystalline, or an amorphous structure; a compound semiconductor including silicon carbide, gallium arsenic, gallium phosphide, indium phosphide, indium arsenide, and indium antimonide; an alloy semiconductor including SiGe, GaAsP, AlInAs, AlGaAs, GaInAs, GaInP, and GaInAsP; any other suitable material; or combinations thereof. The isolation region 114 is formed in trenches between the substrate portions 112, 122. The isolation region 114 has an upper surface level with upper surfaces of the substrate portions 112, 122. Example materials of the isolation regions 114 include, but are not limited to, insulating materials, such as a dielectric material, e.g., silicon oxide, silicon nitride, silicon oxynitride, a combination thereof, or the like.

The IC device 100B further comprise gate electrodes 116, 118, and nanosheet stacks 124, 134. The gate electrode 116 and the nanosheet stack 124 configure the semiconductor device 111. The gate electrode 116 and the nanosheet stack 134 configure the semiconductor device 121. The gate electrodes 116, 118 are formed over the substrate portions 112, 122 and the isolation region 114. The gate electrodes 116, 118 extend along a Y axis transverse to the X axis. In at least one embodiment, the Y axis is perpendicular to the X axis. In some embodiments, the gate electrodes 116, 118 comprise one or more layers of conductive materials including, but not limited to, doped polysilicon, Co, Ru, Al, Ag, Au, W, Ni, Ti, Cu, Mn, Pd, Re, Ir, Pt, Zr, alloys thereof, combinations thereof, or the like. In some embodiments, the gate electrodes 116, 118 further comprise other work function adjusting metals, diffusion barrier materials, glue layers, or the like.

Each of the nanosheet stacks 124, 134 includes a plurality of separated nanosheets correspondingly stacked over the substrate portions 112, 122 along a Z axis which is a thickness direction of the substrate 110. The nanosheet stacks 124, 134 extend along the X axis along which the substrate portions 112, 122 extend. In other words, the nanosheet stacks 124, 134 extend transversely to the gate electrodes 116, 118. A portion of each nanosheet of the nanosheet stacks 124, 134 is surrounded by at least one of the gate electrodes 116, 118. In some embodiments, a nanosheet in the nanosheet stacks 124, 134 is a generally two-dimensional semiconductor slab with a length (along the X axis) or width (along the Y axis) greater than about 110 nm, and a thickness (along the Z axis) less than about 20 nm. Other nanosheet or nanowire configurations are within the scopes of various embodiments. In the example configuration in FIG. 1B, each of the nanosheet stacks 124, 134 comprises four nanosheets. Other numbers of nanosheets in a nanosheet stack are within the scopes of various embodiments.

In some embodiments, the nanosheet stacks 124, 134 and the substrate portions 112, 122 are formed from the same wafer, by performing photolithography and etching operations on the wafer. In at least one embodiment, the nanosheet stack 124 or the nanosheet stack 134 is doped with an N-type impurity, e.g., arsenic, phosphorus, or the like, to form an N-type nanosheet FET, or is doped with a P-type impurity, e.g., boron or the like, to form a P-type nanosheet FET. For example, the nanosheet stack 124 is configured as an N-type nanosheet which configures the semiconductor device 111 as an N-type semiconductor device, e.g., an N-type transistor, whereas the nanosheet stack 134 is configured as a P-type nanosheet which configures the semiconductor device 121 as a P-type semiconductor device, e.g., a P-type transistor. The N-type is an example of one of a first conductivity type and a second conductivity type, and the P-type is an example of the other of the first conductivity type and the second conductivity type.

The stacked nanosheets of the same nanosheet stack 124 or 134 are configured to form a combined channel region and/or a combined source/drain region of the corresponding semiconductor device. For example, the portion of each nanosheet of the nanosheet stack 124 which overlaps the gate electrode 116 is configured as a combined channel region of the semiconductor device 111, while other portions of each nanosheet of the nanosheet stack 124 on opposite sides of the channel region are configured as source/drain regions of the semiconductor device 111. Similarly, the portion of each nanosheet of the nanosheet stack 134 which overlaps the gate electrode 116 is configured as a combined channel region of the semiconductor device 121, while other portions of each nanosheet of the nanosheet stack 134 on opposite sides of the channel region is configured as source/drain regions of the semiconductor device 121.

FIG. 1C is a cross-sectional view of the portion of the IC device 100B, in accordance with some embodiments. The cross-sectional view in FIG. 1C is taken along a line C-C cutting through the gate electrode 116 in FIG. 1B.

As illustrated in FIG. 1C, the semiconductor devices 111, 121 further comprise corresponding gate dielectric layers 126, 136 between the gate electrode 116 and each nanosheet of the corresponding nanosheet stacks 124, 134. In some embodiments, the gate dielectric layers 126, 136 include one or more dielectric materials, including, but not limited to, oxide, nitride, oxynitride, high-k dielectric materials, such as Al₂O₃, HfO₂, ZrO₂, HfOₓN_{y}, ZrOₓN_{y}, HfSiₓO_{y}, ZrSiₓO_{y}, HfSiₓO_{y}N_{z}, ZrSiₓO_{y}N_{z}, TiO₂, Ta₂O₅, La₂O₃, CeO₂, Bi₄Si₂Oi₂, WO₃, Y₂O₃, LaAlO₃, Ba₁₋ₓSrₓTiO₃, PbTiO₃, BaTiO₃ (BTO), SrTiO₃ (STO), BaSrTiO₃ (BST), PbZrO₃, lead-strontium-titanate (PST), lead-zinc-niobate (PZN), lead-zirconate-titanate (PZT), lead-magnesium-niobium (PMN), yttria-stabilized zirconia (YSZ), ZnO/Ag/ZnO (ZAZ), a combination thereof, or the like. In some embodiments, the IC device 100B further comprises a work function adjusting layer (not shown) between the gate electrode 116 and each of the gate dielectric layers 126, 136. In the example configuration in FIG. 1C, the nanosheets in each of the nanosheet stacks 124, 134 have substantially the same width w along the Y axis. Other configurations are within the scopes of various embodiments.

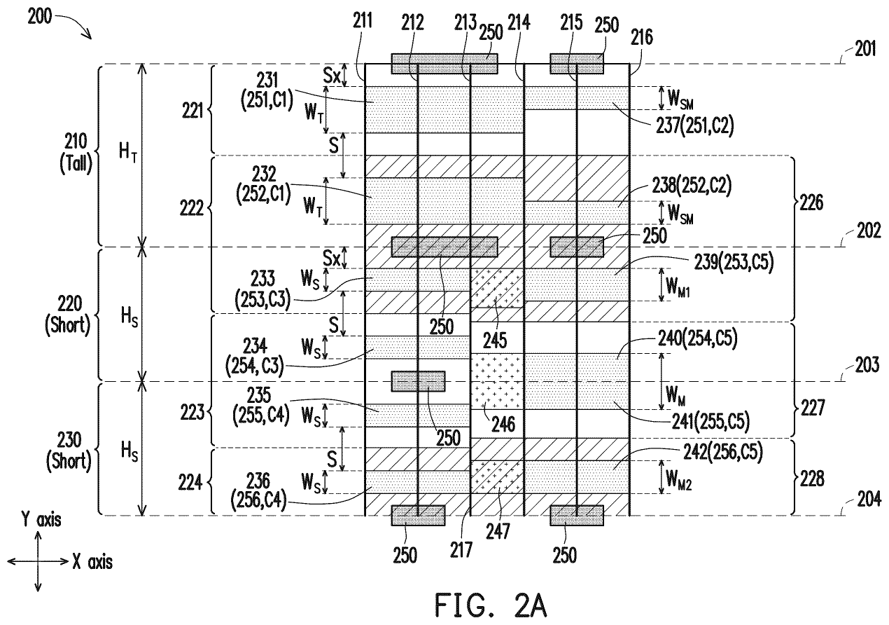

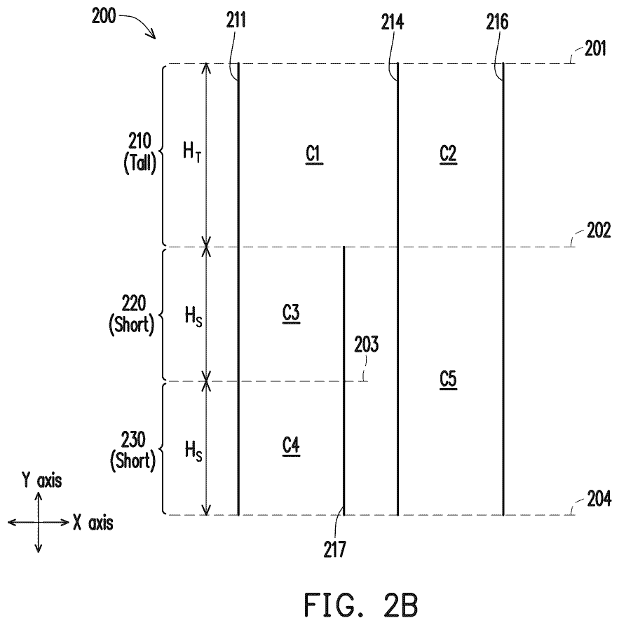

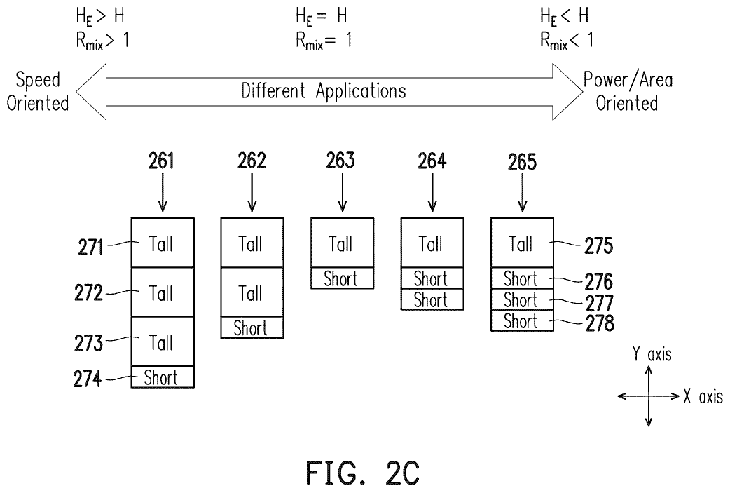

FIG. 2A is a schematic view of an IC layout 200 of a circuit region of an IC device, in accordance with some embodiments. In some embodiments, the circuit region corresponds to the region 103, or a part thereof. In at least one embodiment, the IC device corresponds to one or more of the IC devices 100A, 100B. In some embodiments, the IC layout 200, as well as IC layouts described herein with respect to various embodiments, are generated by an EDA system, such as an APR system, and/or stored in a non-transitory, computer-readable storage medium.

The IC layout 200 comprises a plurality of rows 210, 220, 230 of semiconductor devices. The rows 210, 220, 230 are elongated along the X axis and are arranged side-by-side along the Y axis. The X axis is an example of a first axis, and the Y axis is an example of a second axis transverse to the first axis. In at least one embodiment, the semiconductor devices in the rows 210, 220, 230 correspond to the semiconductor devices 111, 121 and/or comprise GAA devices.

Each of the rows 210, 220, 230 has a pair of boundary lines spaced from each other along the Y axis by a distance corresponding to a height of the row. For example, the row 210 has a pair of boundary lines 201, 202, and a corresponding height H_{T} between the boundary lines 201, 202, the row 220 has a pair of boundary lines 202, 203, and a corresponding height H_{S} between the boundary lines 202, 203, and the row 230 has a pair of boundary lines 203, 204, and a corresponding height H_{S} between the boundary lines 203, 204. The row 210 is an example of a first row, and H_{T} is an example of a first height of the first row along the Y axis. The row 220 is an example of a second row, and H_{S} is an example of a second height of the second row along the Y axis. As described herein, H_{S} is smaller than H_{T} to achieve one or more advantages in one or more embodiments. The row 230 is an example of a third row, and H_{S} is an example of a third height of the third row along the Y axis. In some embodiments, at least one of the boundary lines 201-204 corresponds to a centerline of a power rail, as described herein.

In the example configuration in FIG. 2A, the rows 210, 220, 230 touch each other and share common boundary lines. For example, the rows 210, 220 touch each other at and share the common boundary line 202, and the rows 220, 230 touch each other at and share the common boundary line 203. Other configurations are within the scopes of various embodiments. For example, in at least one embodiment (not shown), two adjacent rows do not share a common boundary line, and are spaced from each other along the Y axis by an empty space that contains no semiconductor devices. Such two rows are sometimes referred to as immediately adjacent non-touching rows. In some embodiments, two rows are considered adjoining each other when the two rows share a common boundary line (e.g., the rows 210, 220) or when the two rows are immediately adjacent non-touching rows.

Each of the rows 210, 220, 230 comprises a first active region of a first conductivity type, and a second active region of a second conductivity type different from the first conductivity type, where the second active region is spaced from the first active region. For example, the row 210 comprises a first active region 251 comprising portions 231, 237 having different active region widths as described herein, and a second active region 252 comprising portions 232, 238 having different active region widths as described herein. One of the active regions 251, 252 is an N-type active region, and the other of the active regions 251, 252 is a P-type active region. For example, the active region 251 is a P-type active region, and the active region 252 is an N-type active region. In some embodiments, an N-type active region corresponds to the nanosheet stack 124, and a P-type active region corresponds to the nanosheet stack 134.

The active regions 251, 252 of the row 210 are spaced from each other along the Y axis by at least a spacing S. For example, the portions 231, 232 of the active regions 251, 252 are spaced from each other along the Y axis by the spacing S, whereas the portions 237, 238 of the active regions 251, 252 are spaced from each other along the Y axis by a spacing greater than the spacing S. In some embodiments, the spacing S is a predetermined minimal active region spacing along the Y axis between immediately adjacent active regions. Two active regions are immediately adjacent when there is no other active region between the two active regions. The spacing S is a design rule to be met to ensure manufacturability and/or operability of IC devices corresponding to the IC layout 200.

Each of the active regions 251, 252 is arranged in a region, e.g., a substrate region, a doped-region, or a well region, of a corresponding conductivity type. For example, the active region 251 is a P-type active region and is arranged in an N-type well region 221, and the active region 252 is an N-type active region and is arranged in a P-type substrate region having portions 222, 226. For simplicity, the reference numeral 222 herein designates the P-type substrate region containing the active region 252. The P-type substrate region 222 extends continuously across the boundary line 202 into the row 220. In some embodiments, the N-type well region 221 extends continuously across the boundary line 201 (upward in FIG. 2A) into another row of semiconductor devices (not shown).

The row 220 comprises a first active region 254 comprising portions 234, 240, and a second active region 253 comprising portions 233, 239. The active regions 253, 254 of the row 220 are spaced from each other along the Y axis by at least the spacing S. For example, the portions 233, 234 of the active regions 253, 254 are spaced from each other along the Y axis by the spacing S, whereas the portions 239, 240 of the active regions 253, 254 are spaced from each other along the Y axis by a spacing greater than the spacing S. In the example configuration in FIG. 2A, the active region 253 is an N-type active region arranged in the P-type substrate region 222, and the active region 254 is a P-type active region arranged in an N-type well region having portions 223, 227. For simplicity, the reference numeral 223 herein designates the N-type well region containing the active region 254. The N-type well region 223 extends continuously across the boundary line 203 into the row 230.

The row 230 comprises a first active region 255 comprising portions 235, 241, and a second active region 256 comprising portions 236, 242. The active regions 255, 256 of the row 230 are spaced from each other along the Y axis by at least the spacing S. For example, the portions 235, 236 of the active regions 255, 256 are spaced from each other along the Y axis by the spacing S, whereas the portions 241, 242 of the active regions 255, 256 are spaced from each other along the Y axis by a spacing greater than the spacing S. The portions 231-242 are sometimes referred to as active regions 231-242.

In the example configuration in FIG. 2A, the active region 255 is a P-type active region arranged in the N-type well region 223, and the active region 256 is an N-type active region arranged in a P-type substrate region having portions 224, 228. For simplicity, the reference numeral 224 herein designates the P-type substrate region containing the active region 256. In some embodiments, the P-type substrate region 224 extends continuously across the boundary line 204 (downward in FIG. 2A) into another row of semiconductor devices (not shown). The active region 240 and the active region 241 are continuous to each other, and are merged into a merged active region sometimes referred to as 240/241.

The active regions 231-242 are functional active regions which, together with functional gate regions as described herein, configure a plurality of semiconductor devices in the rows 210, 220, 230. The IC layout 200 further comprises non-functional, or dummy, active regions 245, 246, 247 which are not configured to form semiconductor devices and/or one or more semiconductor devices formed by the dummy active regions are not electrically coupled to other circuitry in an IC device corresponding to the IC layout 200. In some embodiments, dummy active regions have the same configuration and/or manufactured by the same processes as functional active regions. In the example configuration in FIG. 2A, the dummy active region 245 is arranged in the P-type substrate region 222 and continuous to the active regions 233, 239, the dummy active region 246 is arranged in the N-type well region 223 and continuous to the active regions 234, 235, 240, 241, and the dummy active region 247 is arranged in the P-type substrate region 224 and continuous to the active regions 236, 242. In some embodiments, dummy active regions are configured to isolate and interface active regions of different active region widths in the same well region, substrate region, or dopped region. For example, in the same N-type well region 223, the dummy active region 246 is configured to isolate and interface the active regions 234, 235 on one side and the merged active region 240/241 on the other side. In some embodiments, one or more of the dummy active regions are omitted.

The IC layout 200 further comprises gate regions 211-217 extending along the Y axis across the active regions 231-242. Each of the gate regions 211-212, 214-216 extends across all of the rows 210, 220, 230. The gate region 213 extends across the row 210, and is aligned along the Y axis with the gate region 217 which extends across the rows 220, 230. The widths of the gate regions 211-217 are not illustrated in FIG. 2A, for simplicity. In the example configuration in FIG. 2A, the gate regions 212, 213, 215 are functional gate regions which, together with the active regions 231-242 configure a plurality of semiconductor devices. For example, the gate regions 212, 213 and the active regions 231, 232 configure several semiconductor devices corresponding to those described with respect to FIGS. 1B-1C. The gate regions 212 and 215 further configure, together with the corresponding active regions 233-236 and 237-242, further semiconductor devices. The IC layout 200 comprises several cut-gate-region marks (sometimes referred to as “CPO”) commonly designated by a reference numeral 250 to indicate locations where a gate region is separated into sections. For example, the gate region 212 is cut by four cut-gate-region marks 250 into three sections. In at least one embodiment, centerlines of the cut-gate-region marks 250 coincide with the boundary lines 201-204 overlapping the cut-gate-region marks 250.

The gate regions 211, 214, 217 are non-functional, or dummy, gate regions. Dummy gate regions are not configured to form semiconductor devices together with the underlying active regions, and/or one or more semiconductor devices formed by dummy gate regions together with the underlying active regions are not electrically coupled to other circuitry in an IC device corresponding to the IC layout 200. In at least one embodiment, non-functional, or dummy, gate regions include dielectric material in a manufactured IC device. Other configurations are within the scopes of various embodiments. In some embodiments, dummy gate regions define boundaries of cells as described with respect to FIG. 2B.

FIG. 2B is a simplified schematic view of the IC layout 200, in accordance with some embodiments.

FIG. 2B shows cell boundaries of various cells C1-C5 included in the IC layout 200. Each of the cells C1-C5 comprises semiconductor devices configured by at least one corresponding gate region and at least one corresponding active region, as described with respect to FIG. 2A. The gate regions and active regions are omitted in FIG. 2B. The cell C1 is in the row 210, and has cell boundaries defined by the boundary lines 201, 202 and centerlines of the dummy gate regions 211, 214. The cell C2 is in the row 210, and has cell boundaries defined by the boundary lines 201, 202 and centerlines of the dummy gate regions 214, 216. The cell C3 is in the row 220, and has cell boundaries defined by the boundary lines 202, 203 and centerlines of the dummy gate regions 211, 217. The cell C4 is in the row 230, and has cell boundaries defined by the boundary lines 203, 204 and the centerlines of the dummy gate regions 211, 217. The cell C5 is arranged across the rows 220, 230 and has cell boundaries defined by the boundary lines 202, 204 and the centerlines of the dummy gate regions 214, 216. In a place-and-route operation, e.g., performed by an APR system, cells are placed in an IC layout in abutment with each other at their respective cell boundaries. For example, along the X axis, the cell C1 is placed in abutment with the cell C2 along the common cell boundary defined by the dummy gate region 214. Along the Y axis, the cell C1 is placed in abutment with the cell C3 along the common cell boundary defined by the boundary line 202 which, in one or more embodiments, is defined by a power rail as described herein. The described cell arrangement is an example. Other cell arrangements are within the scopes of various embodiments. Examples of the cells C1-C5 include, but are not limited to, AND, OR, NAND, NOR, XOR, INV, OR-AND-Invert (OAI), MUX, Flip-flop, BUFF, Latch, delay, clock, memory such as static random-access memory (SRAM), de-coupling capacitor, analog amplifier, logic driver, digital driver, or the like.

As can be seen in FIG. 2B, the heights of the rows 210, 220, 230 correspond to cell heights, along the Y axis, of the corresponding cells in the rows. The Y axis is sometimes referred to as a cell height direction. For example, the cells C1, C2 have the cell height H_{T} corresponding to the height of the row 210, the cells C3, C4 have the cell height H_{S} corresponding to the height of the rows 220, 230, and the cell C5 has a cell height of 2H_{S} corresponding to a sum of the cell heights of the rows 220, 230 across which the cell C5 extends.

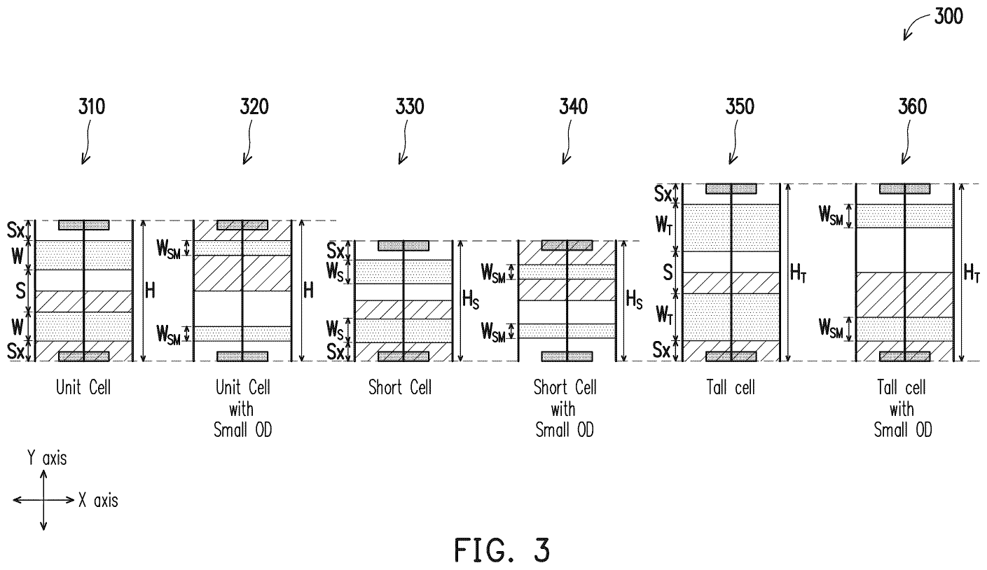

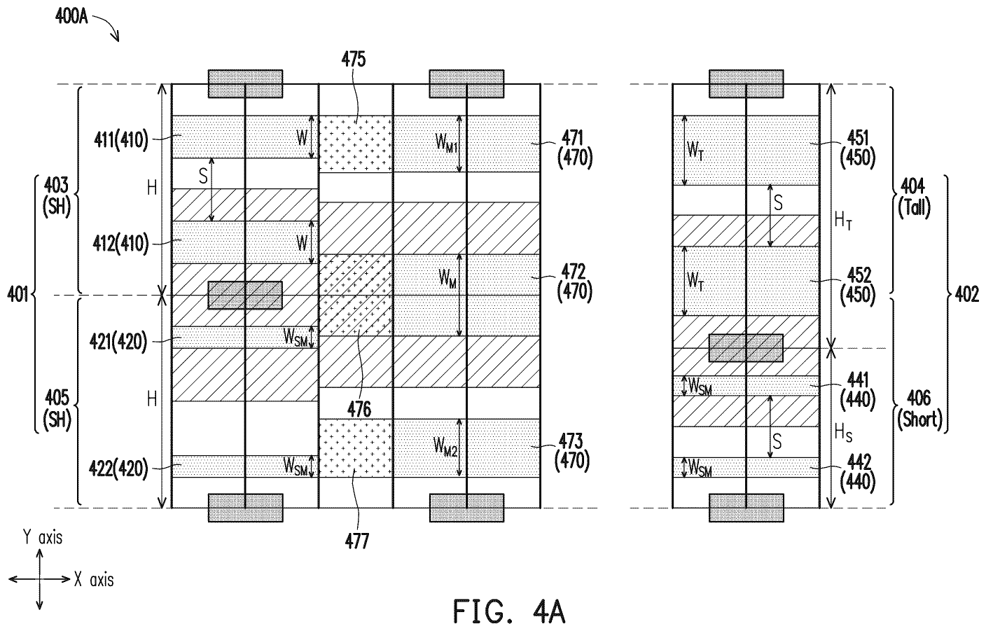

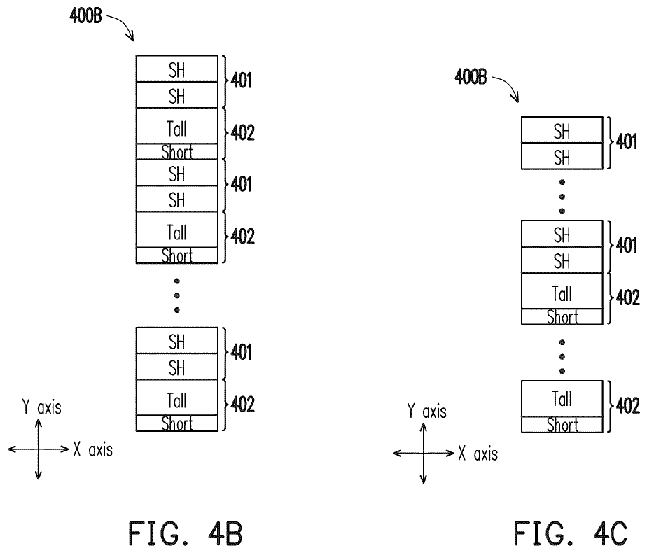

A row (or cell) having the height (or cell height) greater than a unit height of a unit row (or a unit cell height of a unit cell) H is sometimes referred to as a tall row (or tall cell). A row (or cell) having the height (or cell height) smaller than the unit height (or unit cell height) H is sometimes referred to as a short row (or short cell). In the example configuration in FIG. 2B, H_{T}>H, and the corresponding row 210 and cells C1, C2 are sometimes referred to correspondingly as a tall row and tall cells. On the other hand, H>H_{S}, and the corresponding rows 220, 230 and cells C3, C4 are sometimes referred to correspondingly as short rows and short cells. The cell C5 is sometimes referred to as a merged cell, as described herein. Examples of a unit row and unit cells contained therein are described with respect to FIGS. 3, 4A.

Returning to FIG. 2A, the cells C1-C5 are indicated by the active regions included in the cells. For example, the cell C1 comprises, and is indicated by, the active regions 231, 232. The cell C2 comprises, and is indicated by, the active regions 237, 238. The cell C3 comprises, and is indicated by, the active regions 233, 234. The cell C4 comprises, and is indicated by, the active regions 235, 236. The cell C5 comprises, and is indicated by, the active regions 239, 242, as well as the merged active region 240/241. The merged active region 240/241 is arranged between, and has a conductivity type (e.g., P-type) different from a conductivity type (e.g., N-type) of, the active regions 239, 242. The cell C5 is an example of a merged cell which extends along the Y axis across two rows of semiconductor devices, and includes a merged active region. In the example configuration in FIGS. 2A-2B, the cell C5 is a merged cell across two short rows 220, 230. Other merged cell configurations are within the scopes of various embodiments. For example, in one or more embodiments, a merged cell extends across any two touching rows, such as, two short rows, two tall rows, two unit rows, a short row and a tall row, a short row and a unit row, a tall row and a unit row.

Each of the active regions 231-242 has a width, sometimes referred to as “active region width,” along the Y axis. For example, the active regions 231, 232 in the row 210 or the cell C1 have an active region width W_{T}. In some embodiments, the active region width W_{T} is predetermined, and depends on the corresponding cell height (or row height) H_{T} as well as one or more design rules. An example design rule is the spacing S between active regions in the same row, as described herein. A further example design rule is a predetermined minimal spacing Sx, along the Y axis, between an active region and the closest boundary line. For example, as illustrated in FIG. 2A, the spacing between the active region 231 and the closest boundary line 201 is at least Sx. In some embodiments, S=2Sx. Other design rules are within the scopes of various embodiments. In some embodiments, given the cell height H_{T}, W_{T} is a maximal active region width of the active regions 231, 232 when all design rules are met. In some embodiments, corresponding values of W_{T} and H_{T} are predetermined, e.g., for a set of design rules, materials, manufacturing processes, or the like, and are stored, e.g., inside or in association with a cell library.

The active regions 233-236 in the rows 220, 230 or the cells C3, C4 have an active region width W_{S}. In some embodiments, the active region width W_{S} is predetermined, and depends on the corresponding cell height (or row height) H_{S} as well as one or more design rules. In at least one embodiment, the same set of design rules applicable to the cell C1 or the row 210 is also applicable to the cells C3, C4 and the rows 220, 230. In some embodiments, given the cell height H_{S}, W_{S} is a maximal active region width of the active regions 233-236 when all design rules are met. In some embodiments, corresponding values of W_{S} and H_{S} are predetermined, e.g., for a set of design rules, materials, manufacturing processes, or the like, and are stored, e.g., inside or in association with a cell library.

As described herein, H_{S}<H<H_{T}, where H is the unit cell height of a unit cell. Active regions in the unit cell have a unit active region width W, as described with respect to FIGS. 3, 4A. In some embodiments, W_{S}<W<W_{T}. In some embodiments, the unit active region width W is predetermined, and depends on the corresponding unit cell height H as well as one or more design rules. In at least one embodiment, the same set of design rules applicable to the tall cell C1, short cells C3, C4, and rows 210, 220, 230 is also applicable to the unit cell. In some embodiments, given the unit cell height H, W is a maximal active region width of the active regions in the unit cell when all design rules are met. In some embodiments, corresponding values of W and H are predetermined, e.g., for a set of design rules, materials, manufacturing processes, or the like, and are stored, e.g., inside or in association with a cell library.

The active region width W_{T} of the tall row 210 or the tall cell C1 is greater than the active region width W_{S} of the short rows 220, 230 or the short cells C3, C4. As a result, semiconductor devices in the tall cell C1 are configured to provide stronger performance, or faster speed, than semiconductor devices in the short cells C3, C4. With W_{T}>W, the semiconductor devices in the tall cell C1 are configured to also provide stronger performance than semiconductor devices in the unit cell. In other words, the tall cell C1 is configured for performance-oriented improvements. On the other hand, the semiconductor devices in the short cells C3, C4, due to their smaller sizes (e.g., smaller cell height and/or smaller active region width) occupy smaller chip areas and are configured to consume less power in operation than the semiconductor devices in the tall cell C1. With W_{S}<W, the semiconductor devices in the short cells C3, C4 also occupy smaller chip areas and are configured to consume less power in operation than the semiconductor devices in the unit cell. In other words, the short cells C3, C4 are configured for power-and-area-oriented improvements. The described arrangement of rows of semiconductor devices with various cell heights and/or active region widths in an IC layout is an example of a mixed row height configuration (also referred to herein as “mixed row configuration”). In at least one embodiment, an IC layout with a mixed row configuration makes it possible to provide improvements in all PPA aspects as described, for example, with respect to the tall cell C1 and the short cells C3, C4.

In contrast, in other approaches where rows of semiconductor devices with the same cell height and active region width are included in an IC layout, it is difficult to achieve improvements in all PPA aspects. For example, to improve, i.e., increase, performance in accordance with the other approaches, the cell height of all cells is to be increased which would adversely affect (i.e., increase) power and area. For another example, to improve, i.e., decrease, power and area in accordance with the other approaches, the cell height of all cells is to be decreased which would adversely affect (i.e., reduce) performance. A mixed row configuration in accordance with some embodiments overcomes such difficulties experienced by the other approaches, and provides optimizability and/or customizability for different IC layouts and/or different circuit regions of an IC layout to suit one or more particular applications and/or functionalities.

In some embodiments, one or more or all of the following relationships (1)-(5) are satisfied by the tall cell C1 (or the tall row 210) and/or by the short cell C3 or C4 (or the short row 220 or 230):

1.2H≤H_{T}≤1.6H (1)

0.6H≤H_{S}≤0.8H (2)

1.2W≤W_{T}≤2W (3)

0.3W≤W_{S}≤0.8W (4)

1.5≤W_{T}/W_{S}≤2 (5)

In some situations, when one of the relationships (1)-(5) is not satisfied, it is possible that an intended or expected improvement in one of performance, power and area is not achievable.

In some embodiments, all tall cells in a tall row have the same active region width, e.g., W_{T}. In at least one embodiment, however, at least one tall cell in a tall row has an active region width smaller than W_{T}. For example, in FIG. 2A, the tall cell C2 has active regions 237, 238 with a reduced active region width W_{SM}. The active regions 237, 238 with the reduced active region width are sometimes referred to as “small OD.” In some embodiments, a tall cell with small OD, such as the cell C2, is configured to consume less power than a regular tall cell, such as the cell C1, and is placed at a location in a tall row where a performance improvement is not required. As a result, along a tall row in accordance with some embodiments, it is possible to provide performance improvements where required by placing tall cells such as the tall cell C1, and to achieve reduced power consumption where performance improvements are not required by placing tall cells with small OD such as the cell C2. In at least one embodiment, this arrangement further enhances optimizability and/or customizability of the IC layout or a circuit region thereof.

In some embodiments, different tall cells with small OD have different reduced active region widths, i.e., different values of W_{SM}. In at least one embodiment, this arrangement further enhances optimizability and/or customizability of the IC layout or a circuit region thereof, where a balance between performance and power consumption at a location along a tall row is achievable by selecting and placing a tall cell with small OD having an appropriate value of W_{SM} at that location. In some embodiments, for a given H_{T}, various values of W_{SM} for tall cells with small OD are predetermined and stored, e.g., inside or in association with a cell library.

In some embodiments, the following relationship (6) is satisfied by a tall cell with small OD (e.g., the cell C2):

0.3W≤W_{SM}≤0.8W (6)

In some situations, when the relationship (6) is not satisfied by a tall cell with small OD, it is possible that an intended or expected improvement in one of performance, power and area is not achievable.

In some embodiments, the described small OD configuration is applicable to a short cell or a unit cell. For example, a short cell with small OD has a reduced active region width W_{SM}, where W_{SM}<W_{S}. In some embodiments, the relationship (6) is satisfied by a short cell with small OD. In some embodiments, for a given H_{S}, various values of W_{SM} for short cells with small OD are predetermined and stored, e.g., inside or in association with a cell library. In the example configuration in FIG. 2A, it is possible that at least one of the short cells C3, C4 is a short cell with small OD in one or more embodiments. In at least one embodiment, both of the cells C3, C4 are short cells with small OD wherein a value of W_{SM} in the cell C3 is different from a value of W_{SM} in the cell C4.

A unit cell with small OD has a reduced active region width W_{SM}, where W_{SM}<W. In some embodiments, the relationship (6) is satisfied by a unit cell with small OD. In some embodiments, for a given H, various values of W_{SM} for unit cells with small OD are predetermined and stored, e.g., inside or in association with a cell library. In at least one embodiment, one or more advantages described herein with respect to tall cells with small OD are achievable by short cells with small OD and/or by unit cells with small OD. Examples and further details of a short cell with small OD and a unit cell with small OD are described with respect to FIGS. 3, 4A.

In at least one embodiment, it is possible to optimize/customize tall cells (or tall rows) separately from short cells (or short rows) and/or separately from unit cells (or unit rows), e.g., by appropriate values of W_{SM} in tall cells with small OD, short cells with small OD, unit cells with small OD, and/or by the number and/or locations of tall cells with small OD, short cells with small OD, unit cells with small OD in corresponding tall rows, short rows, unit rows.

As described herein, the merged cell C5 comprises a merged active region 240/241 of one conductivity type arranged between active regions 239, 242 of a different conductivity type. In some embodiments, an active region width W_{M1} of the active region 239 is the same as an active region width of the active region 240, and an active region width W_{M2} of the active region 242 is same as an active region width of the active region 241. As a result, an active region width W_{M} of the merged active region 240/241 is a sum of W_{M1} and W_{M2}. In at least one embodiment, W_{M1}=W_{M2} and W_{M}=2W_{M1}=2W_{M2}.

In at least one embodiment, by merging the active regions 240, 241 into the merged active region 240/241, the merged active region 240/241 has a greater active region width W_{M} than those initially included in the component cells (i.e., a first cell with the active regions 239, 240 and a second cell with the active regions 241, 242) before/without merging. The increased active region width W_{M} improves performance of the merged cell C5, in one or more embodiments. The described merged cell configuration in accordance with some embodiments makes it possible to provide performance improvements (i.e., to increase the speed) even in a region with limited active region widths, such as in a region with short rows and/or unit rows. The described performance improvements are also achievable in a region with tall cells, because, as described herein, it is possible in one or more embodiments to merge any two cells or rows, including two tall cells or two tall rows, to configure a merged cell.

In some embodiments, the following relationship (7) is satisfied by a merged cell (e.g., the cell C5):

1W≤W_{M}≤4W (7)

As can be seen from the relationships (3) and (7), in some embodiments, W_{M} of a merged active region is greater than a maximal value (2W) of an active region width W_{T} of a tall cell. In other words, it is possible for a merged cell in one or more embodiments to provide greater speed improvements than a tall cell. In some situations, when the relationship (7) is not satisfied by a merged cell, it is possible that an intended or expected improvement in one of performance, power and area is not achievable.

FIG. 2C includes schematic views of various cell row configurations 261-265 in one or more IC layouts, in accordance with some embodiments.

Each of the cell row configurations 261-265 comprises a set of rows including at least one tall cell and at least one short cell. In at least one embodiment, a set of rows is repeatedly placed multiple times along the Y axis to cover a floorplan of an IC layout or a region thereof. As a result, the IC layout comprises a repeating pattern of the set of rows. Such a repeating pattern of a set of rows is sometimes referred to as a cell array. A cell array in which all rows have the same height is sometimes referred to as a single height (SH) cell array (or a single row height cell array) which has a single row height configuration. In some embodiments, all rows in a single height cell array are unit rows, and the single height cell array is a unit cell array. A cell array including rows with different heights, such as a cell array based on any of the cell row configurations 261-265, is sometimes referred to as a mixed row cell array. An example cell array with a repeating pattern of a set of rows is described with respect to FIGS. 4B, 4C.

In the example configuration in FIG. 2C, the cell row configuration 261 comprises a set of rows including three tall rows 271, 272, 273 and one short row 274. The cell row configuration 262 comprises a set of rows including two tall rows and one short row. The cell row configuration 263 comprises a set of rows including one tall row and one short row. The cell row configuration 264 comprises a set of rows including one tall row and two short rows. The cell row configuration 265 comprises a set of rows including one tall row 275 and three short rows 276, 277, 278. Other cell row configurations having other numbers of tall rows and/or short rows are within the scopes of various embodiments. In at least one embodiment, each of the tall rows, e.g., 271, 272, 273, 275 corresponds to the tall row 210, and/or each of the short rows 274, 276, 277, 278 corresponds to the short row 220 or 230. A specific example of the cell row configuration 264 is described with respect to FIGS. 2A, 2B. In the example configuration in FIG. 2C, all of the tall rows have the same height H_{T} and all of the short rows have the same height H_{S}. Other configurations are within the scopes of various embodiments. for example, it is possible in one or more embodiments that two tall rows in the same cell row configuration (e.g., tall rows 271, 272 in the cell row configuration 261) have different heights greater than H, and/or two short rows in the same cell row configuration (e.g., short rows 276, 277 in the cell row configuration 265) have different heights smaller than H.

As described herein, tall rows with tall cells contained therein are configured for performance, whereas short rows with short cells contained therein are configured for power and area. The number of tall rows, the number of short rows, and the corresponding heights H_{T} and H_{S} in each of the cell row configurations 261-265 determine the applicability of the cell row configuration to improve performance or to improve power and area. In some embodiments, such applicability is represented by an equivalent cell height H_{E} of the cell row configuration. In at least one embodiment, H_{E} is determined through a mixed row ratio Rₘᵢₓ as follows:

Rₘᵢₓ=number of tall rows/number of short rows (8)

H_{E}=(H_{T}×Rₘᵢₓ+H_{S})/(Rₘᵢₓ+1) (9)

In an example, for the cell row configuration 261, Rₘᵢₓ=3, and H_{E}=(3H_{T}+H_{S})/4. In another example, for the cell row configuration 265, Rₘᵢₓ=1/3, and H_{E}=(H_{T}+3H_{S})/4. As illustrated in FIG. 2C, H_{E} and Rₘᵢₓ are increased toward the cell row configuration 261, and are decreased toward the cell row configuration 265. The cell row configuration 263 has Rₘᵢₓ=1. In at least one embodiment, H_{T}+H_{S}=2H, resulting in the cell row configuration 263 having H_{E}=H. H_{E}=H indicates that a cell array including a repeating pattern of the cell row configuration 263 is comparable in terms of performance, power and area to a single height cell array including unit rows of the height H.

H_{E}>H (e.g., for the cell row configurations 261, 262) indicates that the cell row configurations 261, 262 are configured to provide performance improvements over the single height cell array, and are applicable to speed-oriented applications or circuit regions. Between the cell row configurations 261, 262, the cell row configuration 262 is configured to provide smaller performance improvements, but have better power and area parameters, than the cell row configuration 261. In at least one embodiment, the cell row configuration 261 is applicable or preferred in applications or circuit regions where speed is a top priority, whereas the cell row configuration 262 is applicable or preferred in applications or circuit regions where a requirement for speed is not as high and power and area are design considerations.

H_{E}<H (e.g., for the cell row configurations 264, 265) indicates that the cell row configurations 264, 265 are configured to provide power and area improvements over the single height cell array, and are applicable to power-and-area-oriented applications or circuit regions. Between the cell row configurations 264, 265, the cell row configuration 264 is configured to provide smaller power and area improvements, but have a better performance (i.e., higher speed), than the cell row configuration 265. In at least one embodiment, the cell row configuration 265 is applicable or preferred in applications or circuit regions where low power and area are a top priority, whereas the cell row configuration 264 is applicable or preferred in applications or circuit regions where a requirement for low power and area is not as high and speed is a design consideration.

In some embodiments, the following relationship (10) is satisfied by the cell row configurations 261-265:

0.8H≤H_{E}≤1.2H (10)

In at least one embodiment, H<H_{E}≤1.2H indicates performance improvements, whereas 0.8H≤H_{E}<H indicates improvements in power and area. In some situations, when the relationship (10) is not satisfied by a cell row configuration, it is possible that an intended or expected improvement in one of performance, power and area is not achievable with that cell row configuration.

In some embodiments, a plurality of applications and/or circuit regions are associated in advance, e.g., in a look-up table, with different values of H_{E}. For example, a high speed application is associated with a high value of H_{E}, whereas a low power application is associated with a low value of H_{E}. In at least one embodiment, for a given value of H, different values of H_{E} are associated in advance, e.g., in the same or a different look-up table, with corresponding different cell row configurations as described, for example, with respect to FIG. 2C. In some embodiments, different values of H (e.g., for different manufacturing processes, sets of design rules, materials, or the like) result in different cell row configurations being associated with a value of H_{E}.

In at least one embodiment, when an IC layout, or a circuit region thereof, is developed for an application, the look-up table(s) is/are consulted to determine the corresponding H_{E} and then to determine the corresponding cell row configuration. A mixed row cell array is generated as a repeating pattern of the determined cell row configuration. Tall cells and short cells are read from one or more cell libraries and placed, in accordance with circuitry of the circuit region, in the corresponding tall rows and short rows of the mixed row cell array. Routing is performed to couple the placed cells together and/or to other circuitry. As a result, the IC layout, or a circuit region thereof, is generated for the application, with intended improvements in one or more PPA aspects suitable for the application. In at least one embodiment, one or more advantages described herein are achievable by the described methodology and/or cell row configurations.

FIG. 3 includes schematic views of various cells 310-360 placeable in an IC layout, in accordance with some embodiments. In some embodiments, the cells 310-360 are stored in a non-transitory, computer-readable storage medium as part of one or more cell libraries, for example, a cell library 300 as illustrated in FIG. 3. In at least one embodiment, the cells 310-360 all satisfy and/or configured for the same set of design rules, and/or manufacturing processes and/or materials, such that it is possible to include all of cells 310-360 in a same, manufacturable IC layout.

The cell 310 is an example of a unit cell having a cell height H and an active region width W, as described herein. A unit cell is sometimes referred to as a default cell. The cell 310 is placeable in a unit row of the unit height H. An example unit row is described with respect to FIG. 4A. With the spacing S between active regions, the cell 310 has a best active region density (sometimes referred to as “OD density”) among cells with the cell height H. In at least one embodiment, OD density of a cell is determined as a ratio between a sum of active region widths in the cell and the cell height. The cell height of the cell 310 is H=2W+2S (with 2Sx=S). The OD density of the cell 310 is 2W/(2W+2S), or W/(W+S).

The cell 320 is an example of a unit cell with small OD, as described herein. The cell 320 has the cell height H and a reduced active region width W_{SM}, where W_{SM}<W. In at least one embodiment, W_{SM} of the cell 320 satisfies the relationship (6). In at least one embodiment, the cell library 300 comprises variants of the cell 320, i.e., multiple unit cells with small OD like the cell 320, configured for the same function/operation (e.g., variants of a NAND gate cell are NAND gate cells), but with different values of W_{SM}. The cell 320 is placeable in a unit row. In some embodiments, all cells in a unit row are unit cells like the cell 310. In at least one embodiment, all cells in a unit row are unit cells with small OD like the cell 320, with the same W_{SM} or with different values of W_{SM}. In some embodiments, cells in a unit row include one or more unit cells like the cell 310, and one or more unit cells with small OD like the cell 320. In at least one embodiment, cells in a unit row include a part of a merged cell, as described herein.

The cell 330 is an example of a short cell having a cell height H_{S}, where H_{S}<H, and an active region width W_{S}, where W_{S}<W, as described herein. In at least one embodiment, the cell library 300 comprises variants of the cell 330, i.e., multiple short cells like the cell 330, configured for the same function/operation, but with different values of H_{S} and W_{S}. In some embodiments, the cell 330 corresponds the short cell C3 or C4. The cell 330 is placeable in a short row of the corresponding height H_{S}. An example short row is described with respect to FIG. 2A. With the spacing S between active regions, the cell 330 has a best OD density among cells with the cell height H_{S}. In at least one embodiment, the OD density of the cell 330 is W_{S}/(W_{S}+S), and is smaller than the OD density of the cell 310.

The cell 340 is an example of a short cell with small OD, as described herein. The cell 340 has the cell height H_{S} and a reduced active region width W_{SM}, where W_{SM}<W_{S}. In at least one embodiment, W_{SM} of the cell 340 satisfies the relationship (6). In at least one embodiment, the cell library 300 comprises variants of the cell 340, i.e., multiple short cells with small OD like the cell 340, configured for the same function/operation, but with different values of W_{SM}. The cell 340 is placeable in a short row. In some embodiments, all cells in a short row are short cells like the cell 330. In at least one embodiment, all cells in a short row are short cells with small OD like the cell 340, with the same W_{SM} or with different values of W_{SM}. In some embodiments, cells in a short row include one or more short cells like the cell 330, and one or more short cells with small OD like the cell 340. In at least one embodiment, cells in a short row include a part of a merged cell, as described herein.

The cell 350 is an example of a tall cell having a cell height H_{T}, where H_{T}>H, and an active region width W_{T}, where W_{T}>W, as described herein. In at least one embodiment, the cell library 300 comprises variants of the cell 350, i.e., multiple tall cells like the cell 350, configured for the same function/operation, but with different values of H_{T} and W_{T}. In some embodiments, the cell 350 corresponds the tall cell C1. The cell 350 is placeable in a tall row of the corresponding height H_{T}. An example tall row is described with respect to FIG. 2A. With the spacing S between active regions, the cell 350 has a best OD density among cells with the cell height H_{T}. In at least one embodiment, the OD density of the cell 350 is W_{T}/(W_{T}+S), and is greater than the OD density of the cell 310. The higher OD density of the cell 350 indicates that the cell 350 has a better performance (e.g., higher speed) than the cell 310.

The cell 360 is an example of a tall cell with small OD, as described herein. The cell 360 has the cell height H_{T} and a reduced active region width W_{SM}, where W_{SM}<W_{T}. In at least one embodiment, W_{SM} of the cell 360 satisfies the relationship (6). In at least one embodiment, the cell library 300 comprises variants of the cell 360, i.e., multiple tall cells with small OD like the cell 360, configured for the same function/operation, but with different values of W_{SM}. The cell 360 is placeable in a tall row. In some embodiments, all cells in a tall row are tall cells like the cell 350. In at least one embodiment, all cells in a tall row are tall cells with small OD like the cell 360, with the same W_{SM} or with different values of W_{SM}. In some embodiments, cells in a tall row include one or more tall cells like the cell 350, and one or more tall cells with small OD like the cell 360. In at least one embodiment, cells in a tall row include a part of a merged cell, as described herein.

In some embodiments, besides the cells 310-360 and corresponding variants, the cell library 300 further comprises one or more merged cells. In at least one embodiment, a merged cell is obtained by merging active regions of any two cells selected among the cells 310-360 and the corresponding variants. In some embodiments, a merged cell is not pre-stored in a cell library, and is instead generated by an EDA system, by merging two cells read from a cell library, such as the cell library 300.

In some embodiments, cells read from the cell library 300 are placed in rows with the corresponding heights of a cell array generated, for example, as described with respect to FIGS. 2C, 4B, 4C. In at least one embodiment, by selecting a cell to be placed in an IC layout from a cell library based not only on the function/operation the cell is configured to perform, but also on other considerations, such as, the cell height, the active region width, whether the cell is to be placed in a circuit region to be optimized or improved for one or more of performance, power and area, it is possible to achieve one or more advantages described herein, including, but not limited to, PPA improvements, enhanced layout optimizability and/or customizability, or the like.

FIG. 4A is a schematic view of an IC layout 400A of a circuit region of an IC device, in accordance with some embodiments. In some embodiments, the circuit region corresponds to the region 103, or a part thereof. In at least one embodiment, the IC device corresponds to one or more of the IC devices 100A, 100B.

Compared to the IC layout 200 which comprises tall rows and short rows, the IC layout 400A comprises tall rows, short rows and unit rows. For example, the IC layout 400A, in the circuit region illustrated in FIG. 4A, includes a first subset 401 of two unit rows 403, 405, and a second subset 402 of a tall row 404 and a short row 406. The unit rows 403, 405 are labelled as “SH” (single height) in FIG. 4A. The arrangement of the subset 401 and the subset 402 side-by-side is for illustrative purposes and indicating that, in the example configuration in FIG. 4A, H_{S}+H_{T}=2H. In at least one embodiment, the subset 401 and the subset 402 are not aligned along the X axis as illustrated; rather one of the subsets 401, 402 is arranged above or below the other along the Y axis, as described with respect to FIGS. 4B, 4C.

A unit cell 410 including active regions 411, 412 is placed in the unit row 403. In at least one embodiment, the unit cell 410 corresponds to the cell 310. A unit cell 420 including active regions 421, 422 is placed in the unit row 405. In at least one embodiment, the unit cell 420 is a unit cell with small OD and corresponds to the cell 320. A merged cell 470 including active regions 471, 473 on opposite sides of a merged active region 472 is placed across the unit rows 403, 405. The active regions 471, 472, 473 of the merged cell 470 are isolated from the active regions 411, 412, 421, 422 of the cells 410, 420 by dummy active regions 475, 476, 477, in a manner similar to that described with respect to dummy active regions 245, 246, 247. A short cell 440 including active regions 441, 442 is placed in the short row 406. In at least one embodiment, the cell 440 is a short cell with small OD and corresponds to the cell 340. A tall cell 450 including active regions 451, 452 is placed in the tall row 404. In at least one embodiment, the tall cell 450 corresponds to the cell 350.

With H_{S}+H_{T}=2H and an equal number of tall rows and short rows, the IC layout 400A has Rₘᵢₓ=1 and H_{E}=H which indicate that, in overall, the IC layout 400A is relatively comparable to a single height cell array in which all rows are unit rows. However, the arrangement of tall rows and short rows in the IC layout 400A makes it possible to at least locally optimize one or more PPA aspects. For example, in at least one embodiment, cells for performing a function or operation that has speed as a top priority are placed in tall rows or are configured as merged cells. Further cells with about the same considerations for speed on one hand and power and area on the other hand are placed in unit rows. Remaining cells for functions or operations that prefer power and/or area over speed are placed in short rows, or are configured with reduced active region widths. The described localized PPA optimization/improvement is an example.

FIG. 4B and FIG. 4C are schematic views of various cell row configurations 400B, 400C in one or more IC layouts, in accordance with some embodiments.

In FIG. 4B, the cell row configuration 400B comprises a repeating pattern of the subsets 401 and subsets 402 in which the subsets 401 and the subset 402 are alternatingly arranged along the Y axis. In FIG. 4C, the cell row configuration 400B comprises a repeating pattern of the subset 401 in one part (e.g., the upper part of FIG. 4C), and a repeating pattern of the subset 402 in another part (e.g., the lower part of FIG. 4C). Other cell row configurations including the subset 401 and subset 402 are within the scopes of various embodiments. A cell array that includes tall rows, short rows and unit rows as described with respect to FIGS. 4B, 4C is sometimes referred to as an integrated cell array.

The described integrated cell array is an example. Other configurations are within the scopes of various embodiments. For example, in one or more embodiments, the relationship H_{S}+H_{T}=2H and/or the row number relationship of two unit rows per one tall row and one short row are not necessarily satisfied. In some embodiments, other numbers of unit rows, and/or tall rows, and/or short rows are included in an integrated cell array. In at least one embodiment, an integrated cell array is obtained by including one or more unit rows in a cell row configuration of a mixed row cell array. In some embodiments, the rows in the subset 401 or subset 402 are adjoining, and not necessarily touching each other. In some embodiments, one or more advantages described herein are achievable by an IC layout using an integrated cell array, e.g., an integrated cell array based on the cell row configuration 400B or 400C, and/or IC devices manufactured in accordance with such IC layout.

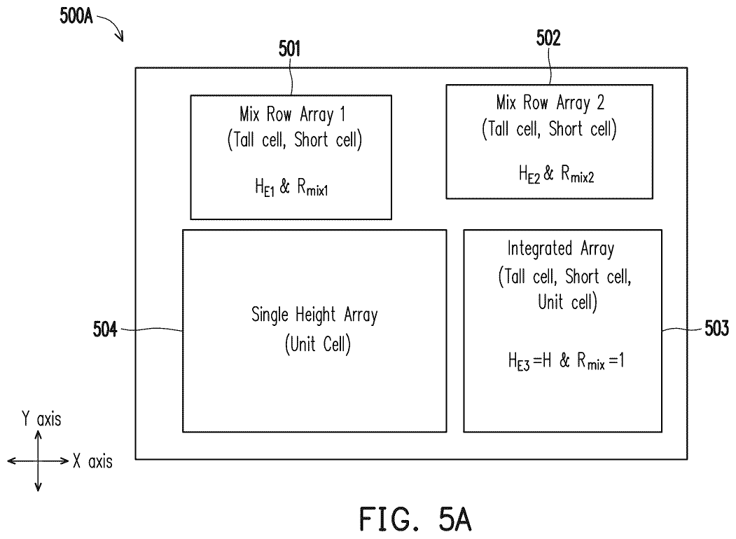

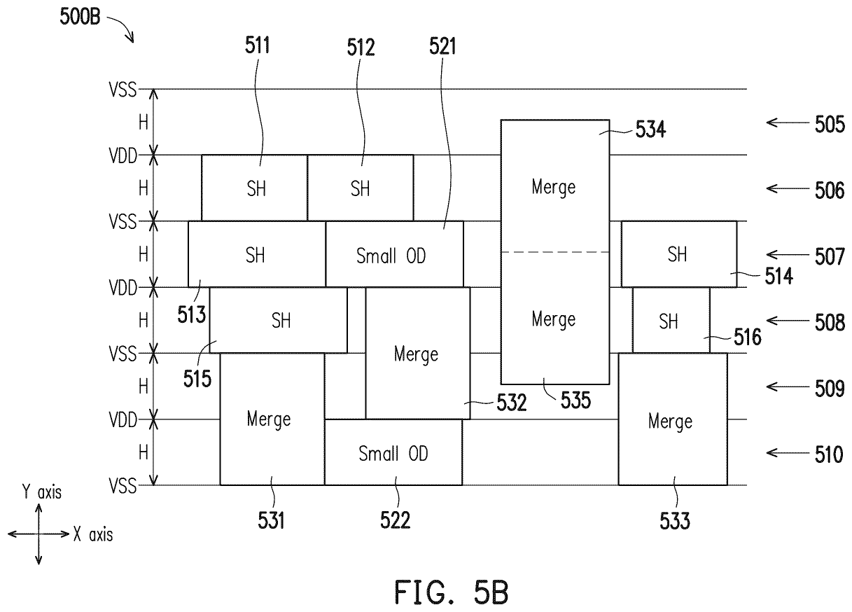

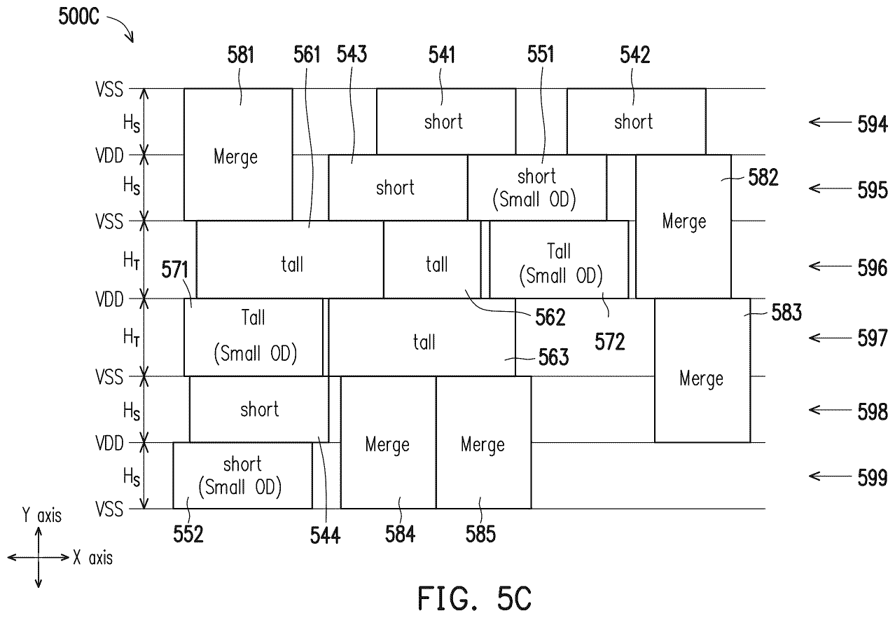

FIG. 5A is a block diagram of an IC device 500A, in accordance with some embodiments. In at least one embodiment, the IC device 500A corresponds to the IC device 100A.

The IC device 500A comprises a plurality of circuit regions 501-504. In at least one embodiment, the circuit regions 501-504 satisfy the same set of design rules, and/or are configured for the same manufacturing processes and/or materials, such that it is possible to manufacture all circuit regions 501-504 together.

In the example configuration in FIG. 5A, the circuit region 501 comprises a mixed row cell array comprising tall cells and short cells placed in corresponding tall rows and short rows which are arranged in a cell row configuration as described, for example, with respect to FIG. 2C. The circuit region 501 has an equivalent cell height H_{E1} and a mixed row ratio Rₘᵢₓ₁ determined as described herein.

The circuit region 502 comprises another mixed row cell array comprising tall cells and short cells placed in corresponding tall rows and short rows which are arranged in a cell row configuration as described, for example, with respect to FIG. 2C. The circuit region 502 has an equivalent cell height H_{E2} and a mixed row ratio Rₘᵢₓ₂. In some embodiments, the circuit region 501 is different from the circuit region 502 in one or more of the number of tall rows, the number of short rows, the cell height of the tall cells, the cell height of the short cells, or the like. In some embodiments, the circuit regions 501, 502 have the same H_{T}, H_{S}, W_{T}, W_{S} which are based on the same H and W, and the circuit regions 501, 502 differ from each other by the number of tall rows and/or the number of short rows. Due to one or more of the described differences, the equivalent cell heights H_{E1} and H_{E2} are different from each other, and/or the mixed row ratios Rₘᵢₓ₁ and Rₘᵢₓ₂ are different from each other. For example, H_{E1}>H_{E2} and the circuit region 501 with the higher H_{E1} is configured for a high speed application, whereas the circuit region 502 with the lower H_{E2} is configured for a low power application.

The circuit region 503 comprises an integrated cell array comprising tall cells, short cells and unit cells placed in corresponding tall rows, short rows and unit rows which are arranged in a cell row configuration as described, for example, with respect to FIGS. 4B, 4C. The circuit region 503 has an equivalent cell height H_{E3} and a mixed row ratio Rₘᵢₓ₃. In some embodiments, the circuit region 503 is different from the circuit region 501 and/or the circuit region 502 in one or more of the number of tall rows, the number of short rows, the cell height of the tall cells, the cell height of the short cells, or the like. In some embodiments, the circuit regions 501, 502, 503 have the same H_{T}, H_{S}, W_{T}, W_{S} which are based on the same H and W, and the circuit region 503 is different from the circuit region 501 and/or the circuit region 502 by the number of tall rows and/or the number of short rows. In at least one embodiment, the circuit region 503 has the same H_{T}, H_{S}, W_{T}, W_{S}, H, W, the number of tall rows, the number of short rows as the circuit region 501 and/or the circuit region 502, and differs from the circuit region 501 and/or the circuit region 502 by the additional inclusion of one or more unit rows. Due to one or more of the described differences, the equivalent cell heights H_{E3} is different from at least one of H_{E1} or H_{E2}, and/or the mixed row ratio Rₘᵢₓ₃ is different from at least one of Rₘᵢₓ₁ or Rₘᵢₓ₂. In at least one embodiment, based on an application to be implemented in the circuit region 503, H_{E3} and Rₘᵢₓ₃ are determined as described herein, to implement the application while achieving one or more intended PPA improvements.

The circuit region 504 is a single height cell array in which all cells and all rows have the same cell height. In other words, all rows in the circuit region 504 are unit rows. In some embodiments, the unit cells in the circuit region 504 have the same H and W which are the basis for determining H_{T}, H_{S}, W_{T}, W_{S} for one or more the circuit regions 501-503. In at least one embodiment, the circuit region 504 makes it possible to achieve one or more PPA improvements locally, by including unit cells, unit cells with small OD, and merged cells, as described with respect to the subset 401 in FIG. 4A. In some embodiments, one or more of the circuit regions 501-504 is/are omitted. One or more advantages described herein are achievable by the IC device 500A.

FIG. 5B is a schematic view of an IC layout 500B of a circuit region of an IC device, in accordance with some embodiments. In some embodiments, the circuit region corresponds to the region 103 or 504, or a part thereof. In at least one embodiment, the IC device corresponds to one or more of the IC devices 100A, 100B, 500A.

The IC layout 500B comprises a single height cell array with various unit rows 505-510 arranged along the Y axis. Each of the unit rows 505-510 has a height H. The IC layout 500B comprises a plurality of power rails configured to supply different power supply voltages, e.g., VDD and VSS. A power rail configured to supply VDD is sometimes referred to as a VDD rail. A power rail configured to carry VSS is sometimes referred to as a VSS rail. In the example configuration in FIG. 5B, VDD rails and VSS rails are alternatingly arranged in the IC layout 500B. A centerline of each power rail coincides with a boundary line between two touching rows. The widths of the power rails are not illustrated in FIG. 5B, for simplicity. The described power rail arrangement is an example. Other power rail arrangements are within the scopes of various embodiments.

The IC layout 500B comprises three types of cells: unit cells, unit cells with small OD, and merged cells. For example, each of regions 511-516 includes one or more unit cells corresponding, e.g., to the cell 310. Each of regions 521-522 includes one or more unit cells with small OD corresponding, e.g., to the cell 320. Each of regions 531-535 includes one or more merged cells each extending across two unit rows. For example, each merged cell in the region 531 extends across two unit rows 509, 510 and corresponds, e.g., to the merged cell 470. In at least one embodiment, the IC layout 500B makes it possible to at least locally achieve one or more PPA improvements. For example, the merged cells in the regions 531-535 provide speed improvements, the unit cells with small OD in regions 521, 522 provide power and/or area improvements, and the unit cells in the regions 511-516 provide a balance among various performance, power and area considerations.

FIG. 5C is a schematic view of an IC layout 500C of a circuit region of an IC device, in accordance with some embodiments. In some embodiments, the circuit region corresponds to the region 103, 501 or 502, or a part thereof. In at least one embodiment, the IC device corresponds to one or more of the IC devices 100A, 100B, 500A. In at least one embodiment, the IC layout 500B and IC layout 500C correspond to various circuit regions of the same IC device.

The IC layout 500C comprises a mixed row cell array with rows 594-599 of various heights arranged along the Y axis. The rows 594, 595, 598, 599 are short rows having a height H_{S}, whereas the rows 596, 597 are tall rows having a height H_{T}. The IC layout 500C comprises a plurality of power rails including alternating VDD rails and VSS rails as described with respect to FIG. 5B.

The IC layout 500C comprises five types of cells: tall cells, tall cells with small OD, short cells, short cells with small OD, and merged cells. For example, each of regions 541-544 includes one or more short cells corresponding, e.g., to the cell 330. Each of regions 551-552 includes one or more short cells with small OD corresponding, e.g., to the cell 340. Each of regions 561-563 includes one or more tall cells corresponding, e.g., to the cell 350. Each of regions 571-572 includes one or more tall cells with small OD corresponding, e.g., to the cell 360. Each of regions 581-585 includes one or more merged cells each extending across two touching rows. For example, each merged cell in the region 581, 584 or 585 extends across two short rows 594, 595 and corresponds, e.g., to the merged cell C5. Each merged cell in the region 582 or 583 extends across one short row 595 or 598 and one tall row 596 or 597.

In some embodiments, depending on the equivalent cell height H_{E} of the IC layout 500C, one or more overall PPA improvements are achievable over the whole IC layout 500C, for example, as described with respect to FIG. 2C. In at least one embodiment, the IC layout 500C makes it possible to further locally achieve one or more PPA improvements. For example, the merged cells in the region 581 provide speed improvements even in areas with short rows intended for power and area. The short cells with small OD in the regions 551, 552 enhance power and area improvements already provided by the short rows 595, 599. The tall cells with small OD in the regions 571, 572 provide power and area improvements even in areas with tall rows intended for speed. In some embodiments, one or more advantages described herein are achievable by the IC layout 500C and/or IC devices manufactured in accordance with the IC layout 500C.

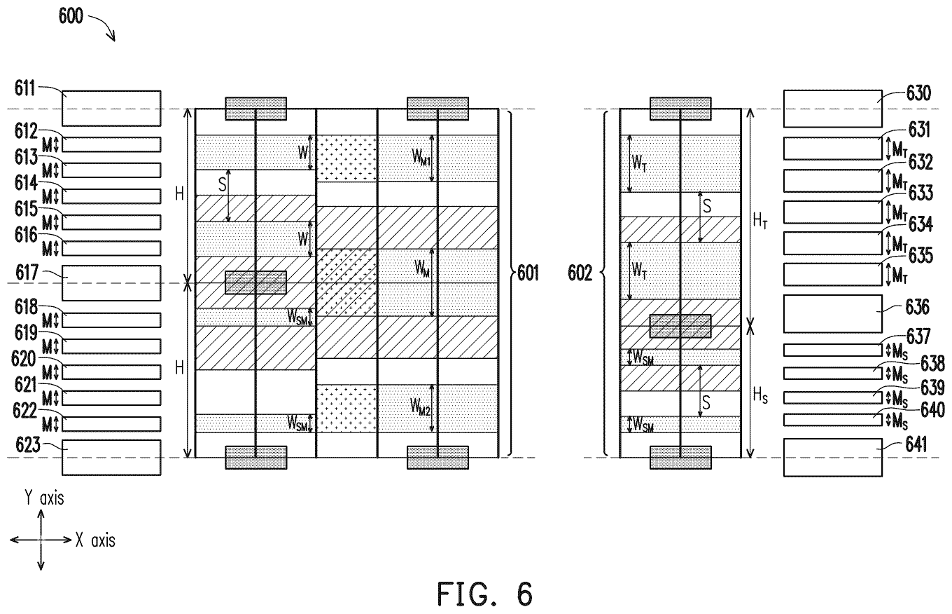

FIG. 6 is a schematic view of an IC layout 600 of a circuit region of an IC device, in accordance with some embodiments. In some embodiments, the circuit region corresponds to the region 103, or a part thereof. In at least one embodiment, the IC device corresponds to one or more of the IC devices 100A, 100B.

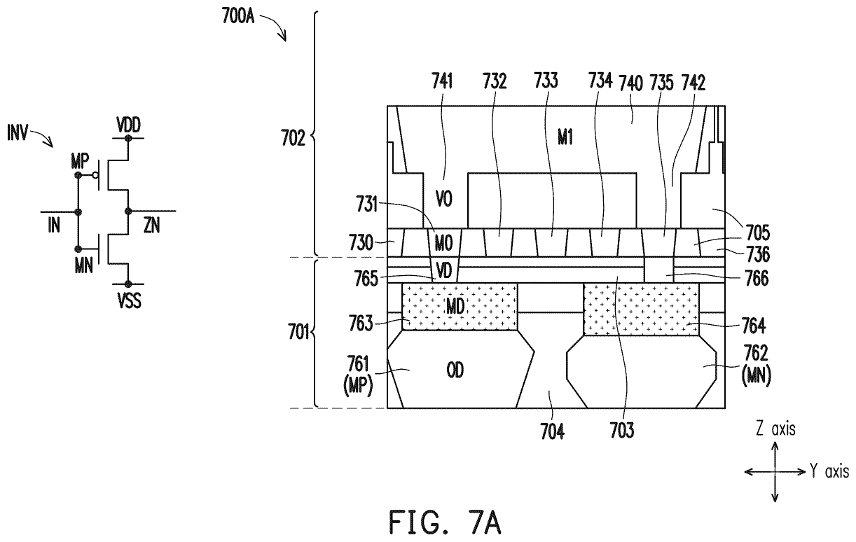

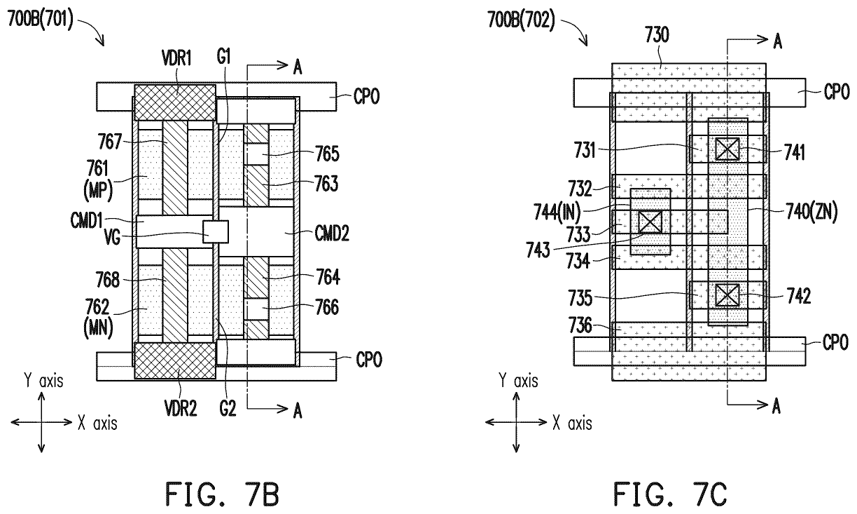

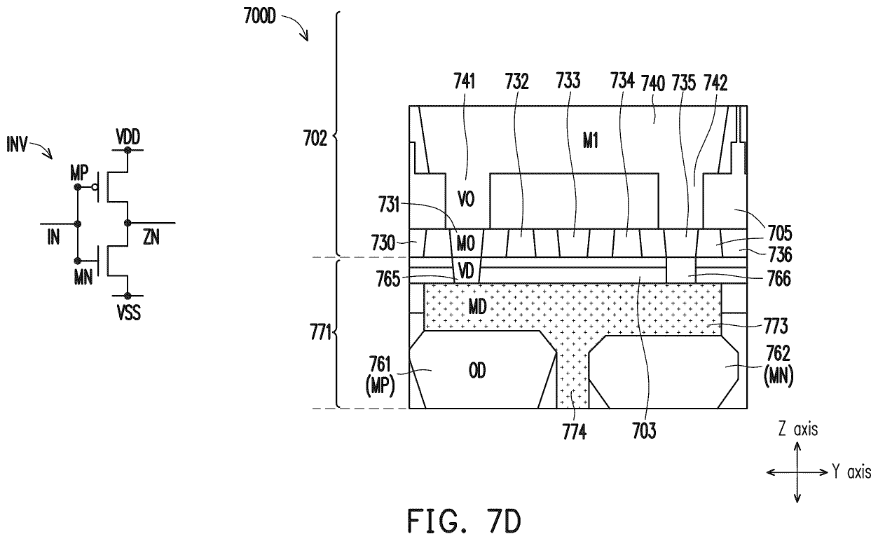

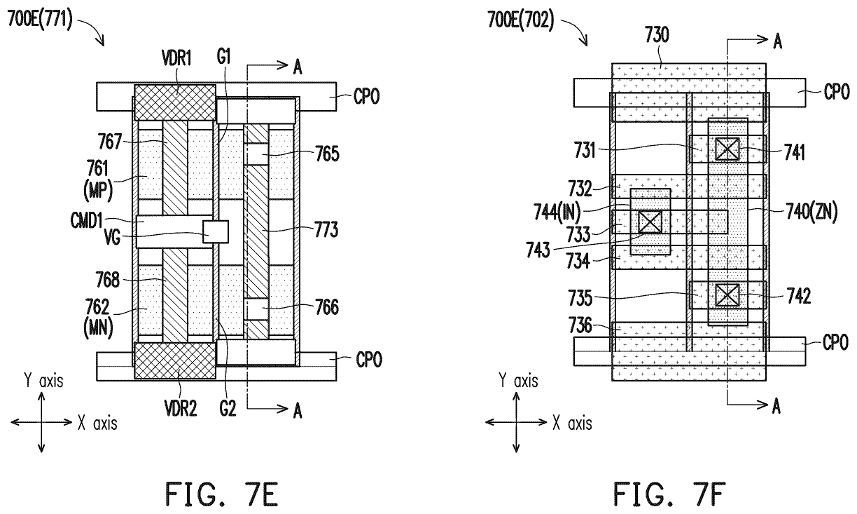

The IC layout 600 comprises a subset 601 of two unit rows, and a subset 602 of a tall row and a short row. In at least one embodiment, the subset 601 corresponds to the subset 401, and/or the subset 602 corresponds to the subset 402. The IC layout 600 further comprises a plurality of conductive patterns in an M0 layer. In some embodiments, the M0 layer is the metal layer closest to the active regions in an IC layout or IC device, whereas an M1 layer which is a metal layer immediately above the M0 layer is the metal layer second closest to the active regions. Further details of the M0 layer and the M1 layer are described with respect to FIGS. 7A, 7C, 7D, 7F. Conductive patterns in the M0 layer or the M1 layer are sometimes correspondingly referred to as M0 conductive patterns or M1 conductive patterns. In FIG. 6, a first set of M0 conductive patterns 611-623 is for the unit rows in the subset 601, whereas a second set of M0 conductive patterns 630-641 is for the tall row and short row in the subset 602. The M0 conductive patterns are shown on a side of the corresponding rows and cells for illustrative purposes. In an actual IC layout, M0 conductive patterns extend along the X axis over the rows and cells, as described with respect to FIGS. 7C, 7F. The two sets of M0 conductive patterns for the subsets 601, 602 differ from each other to achieve one or more PPA improvements, as described herein.

The first set of M0 conductive patterns 611-623 for the unit rows in the subset 601 comprises wider M0 conductive patterns 611, 617, 623 configured as power rails, and having centerlines coinciding with boundary lines of the unit rows, as described with respect to FIGS. 5B, 5C. Remaining M0 conductive patterns in the first set are configured for data or signals, and are sometimes referred to as signal M0 conductive patterns. The signal M0 conductive patterns have a same width (sometimes referred to as “M0 metal width” or “metal width”) M along the Y axis. The metal width M is smaller than the width of the power rails 611, 617, 623 along the Y axis. In at least one embodiment, the first set of M0 conductive patterns 611-623 comprises two subsets each corresponding to and being manufactured by a separate mask. The M0 conductive patterns of the two subsets are alternatingly arranged along the Y axis. For example, a first subset includes M0 conductive patterns 611, 613, 615, 617, 619, 621, 623, whereas a second subset includes M0 conductive patterns 612, 614, 616, 618, 620, 622. The same number, e.g., five, of signal M0 conductive patterns are arranged over each unit row.

The second set of M0 conductive patterns 630-641 for the rows in the subset 602 comprises wider power rails 630, 636, 641. Remaining M0 conductive patterns in the second set are signal M0 conductive patterns, and are narrower than the power rails 630, 636, 641. In at least one embodiment, the second set of M0 conductive patterns 630-641 comprises two subsets each corresponding to and being manufactured by a separate mask. The M0 conductive patterns of the two subsets are alternatingly arranged along the Y axis. For example, a first subset includes M0 conductive patterns 631, 633, 635, 637, 639, 641, whereas a second subset includes M0 conductive patterns 630, 632, 634, 636, 638, 640. In some embodiments, the M0 conductive patterns 611, 613, 615, 617, 619, 621, 623 and 631, 633, 635, 637, 639, 641 correspond to and are manufactured by a first mask, whereas the M0 conductive patterns 612, 614, 616, 618, 620, 622 and 630, 632, 634, 636, 638, 640 correspond to and are manufactured by a second mask.

The signal M0 conductive patterns 631-635 over the tall row in the subset 602 have a metal width M_{T}, where M_{T}>M. A reason is that tall cells in the tall row have a greater active region width W_{T} configured to handle a greater current (to improve speed) than a current handled by unit cells having a smaller active region width W. The greater M_{T} of the signal M0 conductive patterns over the tall row are to reduce a voltage drop (IR drop) related to the greater current handled by the tall cells. In at least one embodiment, for a similar reason, vias coupled to the signal M0 conductive patterns 631-635 over the tall row also have a larger size than vias coupled to the signal M0 conductive patterns 612-616 over the unit row.

The signal M0 conductive patterns 637-640 over the short row in the subset 602 have a metal width M_{S}, where M_{S}<M. A reason is that short cells in the short row are not for speed improvements and have smaller active region width W_{S} or W_{SM} configured to handle a smaller current than the current handled by unit cells having a greater active region width W. The smaller metal width M_{S} of the signal M0 conductive patterns over the short row contribute, in one or more embodiments, to area reduction i.e., an improvement in chip area. In the example configuration in FIG. 6, the number, e.g., four, of signal M0 conductive patterns 637-640 over the short row is smaller than the number, e.g., five, of signal M0 conductive patterns 631-635 over the tall row, for further area improvements. In at least one embodiment, to achieve intended area improvements, it is sufficient either to reduce the number of signal M0 conductive patterns over a short row compared to the unit row or tall row, or to reduce the metal width of signal M0 conductive patterns over the short row compared to the unit row or tall row.

FIG. 7A includes a schematic circuit diagram and a cross-sectional view of a circuit region of an IC device 700A, in accordance with some embodiments. In some embodiments, the IC device 700A corresponds to one or more of the IC devices 100A, 100B, 500A.

In the example configuration in FIG. 7A, the circuit region comprises an inverter INV. As can be seen from the schematic circuit diagram in FIG. 7A, the inverter INV comprises a P-type device MP and an N-type device MN. Gates of the device MP and device MN are coupled to an input IN. A first source/drain of the device MP is coupled to a first source/drain of the device MN and to an output ZN. A second source/drain of the device MP is coupled to VDD, and a second source/drain of the device MN is coupled to VSS.

As can be seen from the cross-sectional view in FIG. 7A, the IC device 700A comprises a first structure 701, and a second structure 702. The structure 701 is formed by an FEOL fabrication, and is sometimes referred to as the FEOL structure 701. The structure 702 is formed over the FEOL structure 701 by a BEOL fabrication, and is sometimes referred to as the BEOL structure 702.

The FEOL structure 701 comprises a substrate (not numbered) which, in one or more embodiments, corresponds to the substrate 110. Active regions 761, 762 (schematically illustrated in the drawing with the label “OD”) are over the substrate, and correspondingly configure the source/drains of the device MP, device MN. In at least one embodiment, the active regions 761, 762 correspond to the nanosheet stacks 134, 124 and/or various active regions described herein. An isolation region 704 is between the active regions 761, 762, and, in one or more embodiments, corresponds to the isolation region 114. The gates of the device MP, device MN are not shown in FIG. 7A. In some embodiments, the gates of the device MP, device MN are continuous to each other and correspond to the gate electrode 116 or 118. Source/drain contacts 763, 764 (schematically illustrated in the drawing with the label “MD”) are correspondingly over and in electrical contact with the active regions 761, 762. The isolation region 704 is also between the source/drain contacts 763, 764. A dielectric layer 703 is over the source/drain contacts 763, 764. Via-to-device (VD) vias 765, 766 are correspondingly over and in electrical contact with the source/drain contacts 763, 764. A via-to-gate (VG) via (not shown in FIG. 7A) is over and in electrical contact with the gates of the device MP, device MN. The VD vias 765, 766 and the VG via are embedded in the dielectric layer 703. Upper surfaces of the dielectric layer 703, the VD vias 765, 766 and the VG via correspond to an upper surface of the FEOL structure 701 on which the BEOL structure 702 is formed.

The BEOL structure 702 is sometimes referred to as a redistribution structure. The redistribution structure comprises a plurality of metal layers and via layers sequentially and alternatingly arranged over the VD, VG vias. The redistribution structure further comprises various interlayer dielectric (ILD) layers (commonly indicated at 705) in which the metal layers and via layers are embedded. The metal layers and via layers of the redistribution structure are configured to electrically couple various elements or circuits of the IC device 700A with each other, and with external circuitry. In the redistribution structure, the lowermost metal layer immediately over and in electrical contact with the VD, VG vias is an M0 (metal-zero) layer, a next metal layer immediately over the M0 layer is an M1 layer, a next metal layer immediately over the M1 layer is an M2 layer, or the like. A via layer Vn is arranged between and electrically couple the Mn layer and the Mn+1 layer, where n is an integer from zero and up. For example, a via-zero (V0) layer is the lowermost via layer which is arranged between and electrically couple the M0 layer and the M1 layer. Other via layers are V1, V2, or the like. Vias in the V0 layer are referred to as V0 vias, vias in the V1 layer are referred to as V1 vias, or the like. For simplicity, metal layers and via layers in the redistribution structure are not fully illustrated in FIG. 7A.

In the example configuration in FIG. 7A, M0 conductive patterns 730-735 are over the FEOL structure 701. The M0 conductive patterns 731, 735 are correspondingly over and in electrical contact with the VD vias 765, 766, and the M0 conductive pattern 733 is over and in electrical contact with the VG. V0 vias 741, 742 are correspondingly over and in electrical contact with the M0 conductive patterns 731, 735. Another V0 via (not shown in FIG. 7A) is over and in electrical contact with the M0 conductive pattern 733 to provide an electrical connection to the gates of the device MP, device MN. An M1 conductive pattern 740 is over and in electrical contact with the V0 vias 741, 742 to electrically couple a source/drain of the device MP in the active region 761 with a source/drain of the device MN in the active region 762. The M1 conductive pattern 740 configures the output ZN. Another M1 conductive pattern (not shown in FIG. 7A) is over and in electrical contact with the V0 via coupled to the gates of the device MP, device MN to configure the input IN.

FIG. 7B and FIG. 7C are schematic views at various layers of an IC layout 700B of the circuit region of FIG. 7A, in accordance with some embodiments. FIG. 7A corresponds to a cross-section taken along line A-A in FIGS. 7B, 7C. FIG. 7B shows a portion of the IC layout 700B that corresponds to the FEOL structure 701. FIG. 7C shows another portion of the IC layout 700B that corresponds to the BEOL structure 702. For simplicity, corresponding components in FIGS. 7A-7C are designated by the same reference numerals.

The portion of the IC layout 700B in FIG. 7B is similar to the layout of a short cell or a unit cell as described herein. The IC layout 700B comprises gates G1, G2 of the device MP, device MN. The gates G1, G2 are continuous to each other, and the VG via is over the gates G1, G2. The IC layout 700B comprises cut-MD masks CMD1, CMD2 which indicate where a source/drain contact is separated into sections. The mask CMD2 corresponds to the isolation region 704 that separates the source/drain contacts 763, 764 in FIG. 7A. The mask CMD1 separates further source/drain contacts 767, 768 over and in electrical contact with further source/drains of the device MP, device MN correspondingly in the active regions 761, 762. Extended VD vias VDR1, VDR2 are correspondingly over and in electrical contact with the source/drain contacts 767, 768, to electrically couple the source/drain contacts 767, 768 correspondingly to the M0 conductive patterns 730, 736 which are correspondingly a VDD rail and a VSS rail.

The portion of the IC layout 700B in FIG. 7C comprises M0 conductive patterns 730-736, V0 vias 741-743, and M1 conductive patterns 740, 744. The V0 via 743 electrically couples the M0 conductive pattern 733 to the M1 conductive pattern 744 which configures the input IN. In some embodiments, the M0 conductive patterns 731-735 correspond to signal M0 conductive patterns over a unit cell or a short cell, as described with respect to FIG. 6.

As can be seen in FIGS. 7A, 7C, a source/drain of the device MP and a source/drain of the device MN are electrically coupled by the M1 conductive pattern 740. This arrangement, in one or more embodiments, is suitable for a cell with not too high OD density, e.g., a unit cell, a short cell, or a cell with small OD. For a cell with high OD density, such as, a tall cell, an addition conductor parallel to the M1 conductive pattern 740 is provided, in one or more embodiments, as described with respect to FIGS. 7D-7F.

FIG. 7D includes a schematic circuit diagram and a cross-sectional view of a circuit region of an IC device 700D, in accordance with some embodiments. In some embodiments, the IC device 700D corresponds to one or more of the IC devices 100A, 100B, 500A, 700A. For simplicity, corresponding components in FIGS. 7A, 7D are designated by the same reference numerals.

The IC device 700D in FIG. 7D is similar to the IC device 700A in FIG. 7A, with differences described herein. The IC device 700D comprises a FEOL structure 771 and the BEOL structure 702. The FEOL structure 771 is different from the FEOL structure 701 of the IC device 700A in that, the FEOL structure 771 comprises an extended source/drain contact 773 that replaces the source/drain contacts 763, 764 of the IC device 700A. The extended source/drain contact 773 continuously extends along the Y axis between the active regions 761, 762. As a result, the active regions 761, 762 are electrically coupled with each other by a pair of parallelly coupled conductors, i.e., the extended source/drain contact 773 and the M1 conductive pattern 740, to reduce resistance (sometimes referred to as “drain side resistance”). In the example configuration in FIG. 7D, the extended source/drain contact 773 further has a section 774 extends downwardly along the Z axis. In some embodiments, the section 774 of the extended source/drain contact 773 further contacts, along the Y axis, the active regions 761, 762 to further reduce resistance. In at least one embodiment, the section 774 is omitted.

FIG. 7E and FIG. 7F are schematic views at various layers of an IC layout 700E of the circuit region of FIG. 7D, in accordance with some embodiments. FIG. 7D corresponds to a cross-section taken along line A-A in FIGS. 7E, 7F. FIG. 7E shows a portion of the IC layout 700E that corresponds to the FEOL structure 771. FIG. 7F shows another portion of the IC layout 700E that corresponds to the BEOL structure 702. For simplicity, corresponding components in FIGS. 7A-7F are designated by the same reference numerals.

The portion of the layout 700E in FIG. 7F is the same as the portion of the IC layout 700B in FIG. 7C. The portion of the layout 700E in FIG. 7E is similar to the portion of the layout 700B in FIG. 7B, with a difference being that the mask CMD2 of the IC layout 700B is not included in the IC layout 700E. As a result, the extended source/drain contact 773 in the IC layout 700E is not separated into source/drain contacts 763, 764 as in the IC layout 700B, and extends continuously between the active regions 761, 762, to configure, together with the M1 conductive pattern 740, a pair of parallelly coupled conductors as described herein.

In at least one embodiment, the parallel coupling arrangement described with respect to FIGS. 7D-7F is suitable for a cell with high OD density, such as, a tall cell. Such an arrangement, in one or more embodiments, reduces the resistance between the source/drains, e.g., drains, of the device MP, device MN, thereby increasing the current and providing speed improvements. The extended source/drain contact 773 potentially creates additional parasitic capacitance with an adjacent conductive structure, e.g., a gate electrode. However, in at least one embodiment, the increased current outweighs any adverse effect related to potentially created additional parasitic capacitance, and speed improvements are achievable by the extended source/drain contact 773.

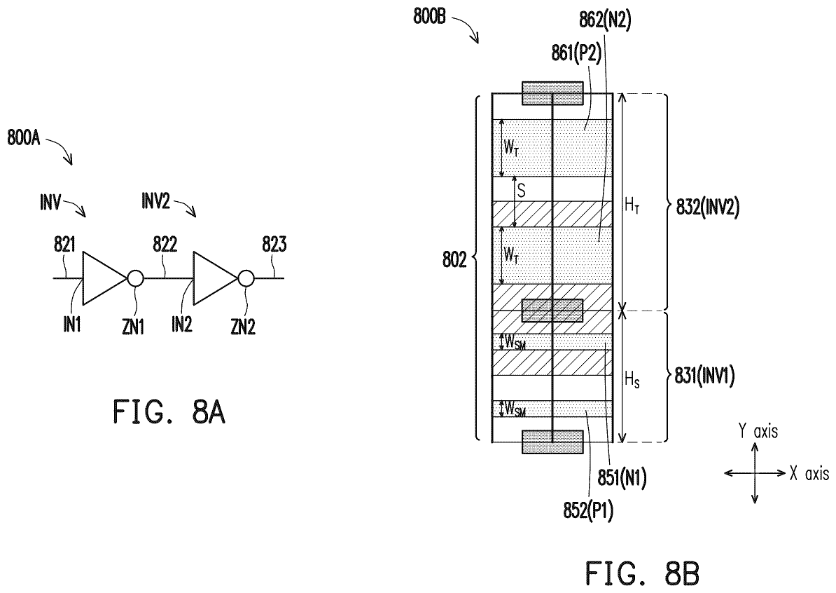

FIG. 8A is a schematic circuit diagram of a circuit region 800A of an IC device, in accordance with some embodiments. In some embodiments, the circuit region 800A corresponds to the region 103, or a part thereof. In at least one embodiment, the IC device corresponds to one or more of the IC devices 100A, 100B, 500A, 700A, 700D.

The circuit region 800A comprises a multi-stage circuit, such as a buffer, an AND gate, an OR gate, or the like. In the example configuration in FIG. 8A, the multi-stage circuit comprises two stages, each being an inverter. Specifically, the first stage comprises an inverter INV1, and the second stage comprises an inverter INV2. In at least one embodiment, the inverters INV1, INV2 correspond to the inverter INV described with respect to FIGS. 7A-7F. Other numbers of stages are within the scopes of various embodiments. Other circuit configurations for each stage are also within the scopes of various embodiments.

The inverter INV1 has an input IN1, and an output ZN1. The inverter INV2 has an input IN2, and an output ZN2. The input IN2 of the inverter INV2 is coupled to the output ZN1 of the inverter INV1. The inverter INV1 is configured to receive, at the input IN1, an input signal 821. The inverter INV1 is configured to, based on the input signal 821, output an intermediate signal 822 at the output ZN1. The intermediate signal 822 is input, through the input IN2, to the inverter INV2 which is configured to, based on the intermediate signal 822, output an output signal 823 at the output ZN2. In some embodiments, to achieve one or more PPA improvements in the multi-stage circuit, the inverter INV1 as the first stage is configured to reduce input impedance and/or capacitance, whereas the inverter INV2 as the second stage is configured to provide a larger driving current than that of the inverter INV1. As a result, it is possible in one or more embodiments to achieve an improved stage ratio and performance for the multi-stage circuit. An example layout for this multi-stage circuit is described with respect to FIG. 8B.

FIG. 8B is a schematic view of an IC layout 800B of the circuit region 800A in FIG. 8A, in accordance with some embodiments.

The IC layout 800B comprises a short cell 831 with the cell height H_{S}, and a tall cell 832 with the cell height H_{T}. The cells 831, 832 are arranged along the Y axis in a configuration 802 which, in one or more embodiments, corresponds to the configuration of the subset 402 or 602. The cell 831 comprises an active region 851 configuring an N-type device N1, and an active region 852 configuring a P-type device P1. Although not illustrated in FIG. 8B, the cell 831 further comprises various conductive structures, vias, and patterns corresponding to those described with respect to one or more of FIGS. 7B, 7C, 7E, 7F. The various conductive structures, vias, and patterns couple the P-type device P1 and the N-type device N1 into an inverter corresponding to the inverter INV1.

The cell 832 comprises an active region 861 configuring a P-type device P2, and an active region 862 configuring an N-type device N2. Although not illustrated in FIG. 8B, the cell 832 further comprises various conductive structures, vias, and patterns corresponding to those described with respect to one or more of FIGS. 7B, 7C, 7E, 7F. The various conductive structures, vias, and patterns couple the P-type device P2 and the N-type device N2 into an inverter corresponding to the inverter INV2.

As described with respect to FIG. 8A, the output of the inverter INV1 in the cell 831 is coupled to the input of the inverter INV2 in the cell 832. In an example, the cell 832 has a layout as shown in FIG. 7C, whereas the cell 831 has a layout as shown FIG. 7C but flipped horizontally across the Y axis. A single M1 conductive pattern extends continuously from the cell 831 into the cell 832, and configures both the output of the cell 831 and the input of the cell 832. As a result, the output of the inverter INV1 in the cell 831 is coupled to the input of the inverter INV2 in the cell 832 to form a multi-stage circuit, as described with respect to FIG. 8A.

In the IC layout 800B, the cell 831 is a short cell with small OD, e.g., as described with respect to the cell 340. In at least one embodiment, the cell 831 is a short cell, e.g., as described with respect to the cell 330. Due to the reduced size(s), e.g., cell height and/or active region width, of the cell 831, the requirement(s) for reduced input impedance and/or low capacitance of the first stage configured by the cell 831 is/are achievable. The cell 832, on the other hand, is a tall cell, e.g., as described with respect to the cell 350. As described herein, such a tall cell has a greater current than a short cell. As a result, the requirement for high driving current of the second stage configured by the cell 832 is achievable. In some embodiments, by configuring the first stage of a multi-stage circuit in a short cell and configuring the second stage of the multi-stage circuit in a tall cell, it is possible to achieve one or more PPA improvements as described herein.

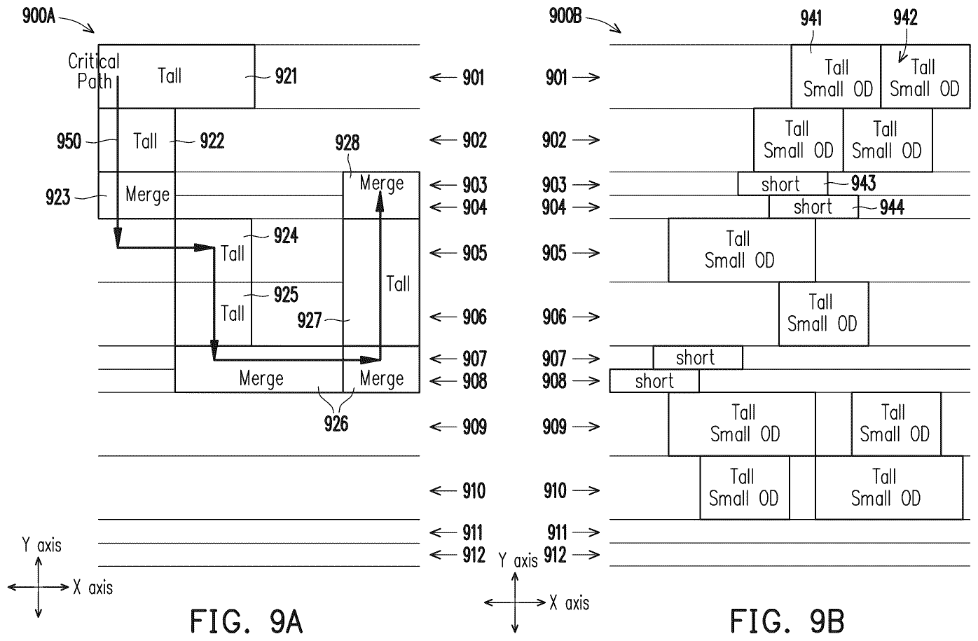

FIG. 9A is a schematic view of an IC layout 900A of a circuit region of an IC device, in accordance with some embodiments. In some embodiments, the circuit region corresponds to the region 103, or a part thereof. In at least one embodiment, the IC device corresponds to one or more of the IC devices 100A, 100B, 500A, 700A, 700D.

The IC layout 900A comprises a mixed row cell array with rows 901-912 of various heights arranged along the Y axis. The rows 901-902, 905-906, 909-910 are tall rows having a height H_{T} (not shown in FIG. 9A), whereas the rows 903-904, 907-908, 911-912 are short rows having a height H_{S} (not shown in FIG. 9A). In some embodiments, the IC layout 900A comprises a plurality of power rails including alternating VDD rails and VSS rails along the boundary lines between the rows, as described with respect to FIG. 5B.

During a design stage, a critical path 950 is identified in the IC layout 900A. A critical path is a timing sensitive path through which signals propagate during operation. In an example, a critical path is a path having a time delay that does not meet (i.e., is greater than) a timing requirement. In further example, a critical path is a path with a long time delay (in some situations, with the longest time delay) in a circuit region of an IC device, or in the whole IC device. A long time delay is a delay that might satisfy the timing requirement but is still greater than a predetermined threshold. Time delays of various paths in an IC design of an IC device are estimated during the design stage by, e.g., one or more simulations performed before or after an APR operation. Based on the result of such simulations, one or more critical paths are identified. In some embodiments, reducing the time delay of a critical path is either necessary to meet the timing requirement or desirable to improve performance of the IC device.

In the example configuration in FIG. 9A, once a critical path, e.g., the critical path 950, has been identified, improvements are made to the IC design or the IC layout 900A to reduce the time delay of the critical path 950. To reduce the time delay of the critical path 950 in the IC layout 900A, rerouting and/or re-configuring one or more cells in the IC layout 900A is/are performed, in one or more embodiments, to route the critical path 950 through cells configured for speed or performance, e.g., through tall cells and/or merged cells. For example, FIG. 9A shows the critical path 950, after improvements to the IC layout 900A, as being routed through tall cells 921, 922, 924, 925, 927 and merged cells 923, 926, 928. In some embodiments, reconfiguring, e.g., merging, cells in short rows into one or more merged cells is performed to provide the merged cells 923, 926, 928. In at least one embodiment, as described herein, it is possible to configure a merged cell to provide better performance (e.g., higher speed, lower time delay) than a tall cell. The merged cells 923, 926, 928 make it possible to provide high performance and reduce time delays even when the critical path 950 passes through short rows which are generally not configured for high speed. In at least one embodiment, using one or more merged cells further shortens the critical path 950, thereby reducing the time delay of the critical path and/or reducing the dragging effect observed when the critical path is too long and passes through unnecessary rows. In some embodiments, after improvements have been made, one or more simulations are re-executed to confirm that the path 950 is no longer a critical path. In at least one embodiment, the described routing and/or merged cell placement to reduce time delays of paths is/are performed at the very first APR operation when an IC layout is generated from an IC design (IC schematic), rather than as improvements to an existing IC layout.

FIG. 9B is a schematic view of an IC layout 900B of a circuit region of an IC device, in accordance with some embodiments. In some embodiments, the circuit region corresponds to the region 103, or a part thereof. In at least one embodiment, the IC device corresponds to one or more of the IC devices 100A, 100B, 500A, 700A, 700D. In at least one embodiment, the IC layout 900A and IC layout 900B are parts of the same IC layout for the same IC device. For simplicity, corresponding components in FIGS. 9A, 9B are designated by the same reference numerals.

Compared to the IC layout 900A which shows examples of cells along a critical path (sometimes referred to as “critical cells”), the IC layout 900B shows examples of cells outside a critical path (sometimes referred to as “non-critical cells”). In some embodiments, non-critical cells are not required to provide a high current or high speed, and are configured to have small active region widths to improve (e.g., reduce) power and/or area. In the example configuration in FIG. 9B, non-critical cells are configured by tall cells with small OD, short cells, or short cells with small OD. Two example tall cells 941, 942 with small OD, and two short cells 943, 944 are designated in FIG. 9B. In at least one embodiment, at least one of the cells 943, 944 is a short cell with small OD. In some embodiments, the tall cells with small OD, short cells and short cells with small OD in the IC layout 900B correspond to the cells 360, 330, 340. In at least one embodiment, using tall cells with small OD for non-critical cells improves at least power consumption, whereas using short cells and/or short cells with small OD for non-critical cells improves both power and area.

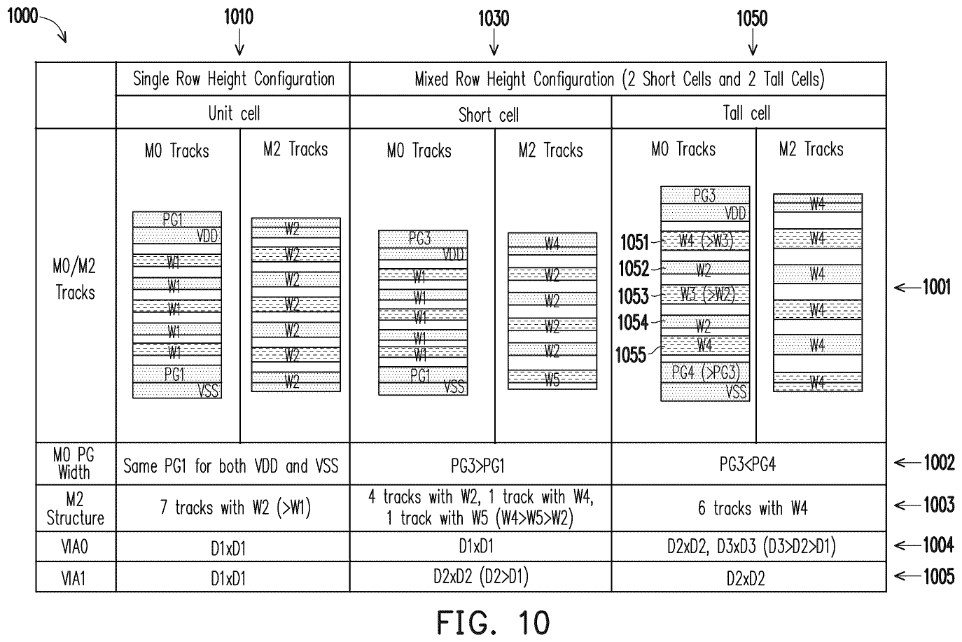

FIG. 10 is a table 1000 showing routing features of various cells placeable in an IC layout, in accordance with some embodiments. Example IC layouts are described with respect to one or more of FIGS. 2A-2C, 3, 4A-4C, 5A-5B, 6, 7B-7C, 7E-7F, 8B, 9A, 9B.

In some embodiments, routing features include BEOL features, such as, metal layers, via layers, or the like, as described with respect to FIGS. 6, 7A, 7D. In the example in FIG. 10, the routing features comprise M0 tracks, M2 tracks, M0 PG width, M2 structure, VIA0, and VIA1, correspondingly in rows 1001-1005 of the table 1000. M0 tracks comprise widths and an arrangement of M0 conductive patterns, e.g., as described with respect to FIG. 6. M2 tracks comprise widths and an arrangement of M2 conductive patterns. M0 PG (power-ground) width indicates widths of M0 conductive patterns configured as VDD rails (power) and VSS rail (ground). M2 structure comprises further details for M2 tracks. VIA0 comprises dimensions of V0 vias. VIA1 comprises dimensions of V1 vias. Other routing features are within the scopes of various embodiments.

The routing features are shown in FIG. 10 for three example cells, i.e., a unit cell in column 1010, a short cell in column 1030, and a tall cell in column 1050 of the table 1000. The unit cell shown in column 1010 is placeable in a single height cell array of the single row height configuration, e.g., as described with respect to FIGS. 5A-5B. The short cell and the tall cell shown correspondingly in columns 1030 and 1050 are placeable in a mixed row cell array of a mixed row height configuration, with two short cells and two tall cells, e.g., as described with respect to FIGS. 9A-9B. In some embodiments, the unit cell, short cell, tall cell shown in table 1000 are placeable in an integrated cell array, as described with respect to FIGS. 4A-4C, 5A, 6. In at least one embodiment, the short cell and the tall cell shown in table 1000 are placeable in other mixed row configurations, as described with respect to FIGS. 2A-2C, 8B. In some embodiments, the routing features shown in FIG. 10 for a unit cell are also applicable to a unit cell with small OD, and a portion of a merged cell over a unit row. The routing features shown in FIG. 10 for a short cell are also applicable to a short cell with small OD, and a portion of a merged cell over a short row. The routing features shown in FIG. 10 for a tall cell are also applicable to a tall cell with small OD, and a portion of a merged cell over a tall row.

For the unit cell in column 1010 of the table 1000, the M0 tracks correspond to those described with respect to the unit cell in FIG. 6. Five signal M0 conductive patterns having a width W1 (corresponding to the width M in FIG. 6) are arranged along the Y axis between two M0 conductive patterns configured correspondingly as a VDD rail and a VSS rail. The VDD rail and the VSS rail have the same width PG1, where PG1>W1. For the M2 tracks, seven M2 conductive patterns are arranged over the cell, and all have the same width W2, where W2>W1. V0 vias and V1 vias have the same dimension D1×D1.

For the short cell in column 1030 of the table 1000, the M0 tracks are similar to those of the unit cell in column 1010, except that the VDD rail has a width PG3 greater than the width PG1 of the VSS rail. For the M2 tracks, four M2 conductive patterns, which do not overlap the VDD and VSS rails and have the width W2, are arranged between the VDD rail and VSS rail. One M2 conductive pattern overlaps the VSS rail and has a width W5. Another M2 conductive pattern overlaps the VDD rail and has a width W4, where W4>W5>W2. V0 vias have the same dimension D1×D1 as V0 vias for the unit cell, whereas V1 vias have a greater dimension D2×D2, where D2>D1.

For the tall cell in column 1050 of the table 1000, the VDD rail has the same width PG3 as for the short cell in column 1030. The VSS rail has a greater width PG4, where PG4>PG3. Two signal M0 conductive patterns 1052, 1054 have the width W2. A signal M0 conductive pattern 1053 between the signal M0 conductive patterns 1052, 1054 has a width W3, where W3>W2. Two signal M0 conductive patterns 1051, 1055 correspondingly adjacent the VDD rail and VSS rail have a width W4, where W4>W3. In some embodiments, the M0 conductive patterns 1051, 1053, 1055 correspond to one M0 mask, whereas VDD rail, VSS rail and M0 conductive patterns 1052, 1054 correspond to another M0 mask. For the M2 tracks, two M2 conductive patterns correspondingly overlap the VDD and VSS rails, and four M2 conductive pattern are arranged between, without overlapping, the VDD and VSS rails. All six M2 conductive patterns have the same width W4. V0 vias include first V0 vias with the dimension D2×D2, and second V0 vias with a greater dimension D3×D3, where D3>D2>D1. The first V0 vias with the smaller dimension D2×D2 are for coupling with the M0 conductive patterns 1052, 1054 with the smaller width W2. The second V0 vias with the greater dimension D3×D3 are for coupling with the M0 conductive patterns 1051, 1053, 1055 with the greater width W4 or W3. V1 vias have the dimension D2×D2.

In the example configuration in FIG. 10, compared to the unit cell in column 1010 and the short cell in column 1030, the tall cell in column 1050 has wider M0 conductive patterns and M2 conductive patterns, and also larger V0 vias, for lower resistance and greater speed. The narrower signal M0 conductive patterns and M2 conductive patterns for the unit cell in column 1010 and the short cell in column 1030 are configured to improve power and/or area. In some embodiments, the mixed row cell array with short cells and tall cells and the corresponding routing features shown in columns 1030, 1050 provides performance improvements over the single height cell array with the unit cell in column 1010. In at least one embodiment, the performance improvements include a speed increase of about 4.5% at the maximal operating frequency of the cell arrays.

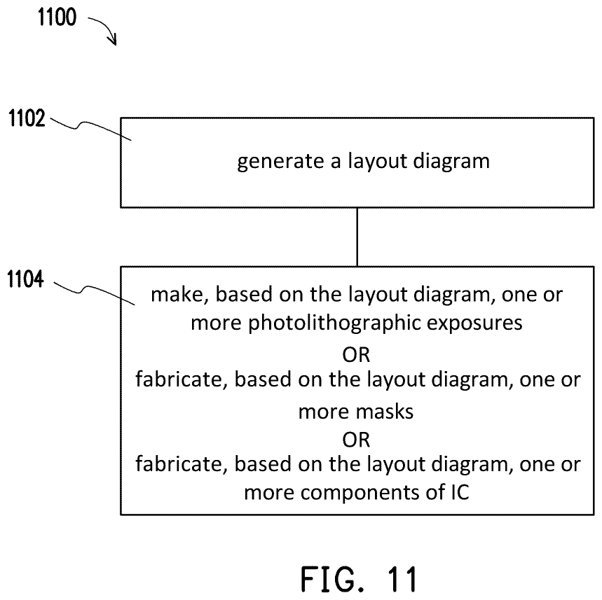

FIG. 11 is a flowchart of a method 1100 of designing and/or manufacturing an IC device, in accordance with some embodiments. In some embodiments, the method 1100 is usable for designing and/or manufacturing one or more IC devices as described herein. The method 1100 is implementable, for example, using an EDA system discussed below, and/or a manufacturing system discussed below, in accordance with some embodiments.

At operation 1102, a layout diagram is generated which, among other things, includes one or more of layouts for various circuits as disclosed herein, or the like. Operation 1102 is implementable, for example, using an EDA system discussed below, in accordance with some embodiments. Examples of layout diagrams obtained at operation 1102 comprise one or more layout diagrams described herein.

At operation 1104, based on the layout diagram, at least one of (A) one or more photolithographic exposures are made or (B) one or more semiconductor masks are fabricated or (C) one or more components in a layer of an IC device are fabricated. Operation 1104 is implementable, for example, using a manufacturing system discussed below, in accordance with some embodiments. Examples of IC devices obtained at operation 1104 comprise one or more IC devices described herein. In some embodiments, operation 1104 is omitted.

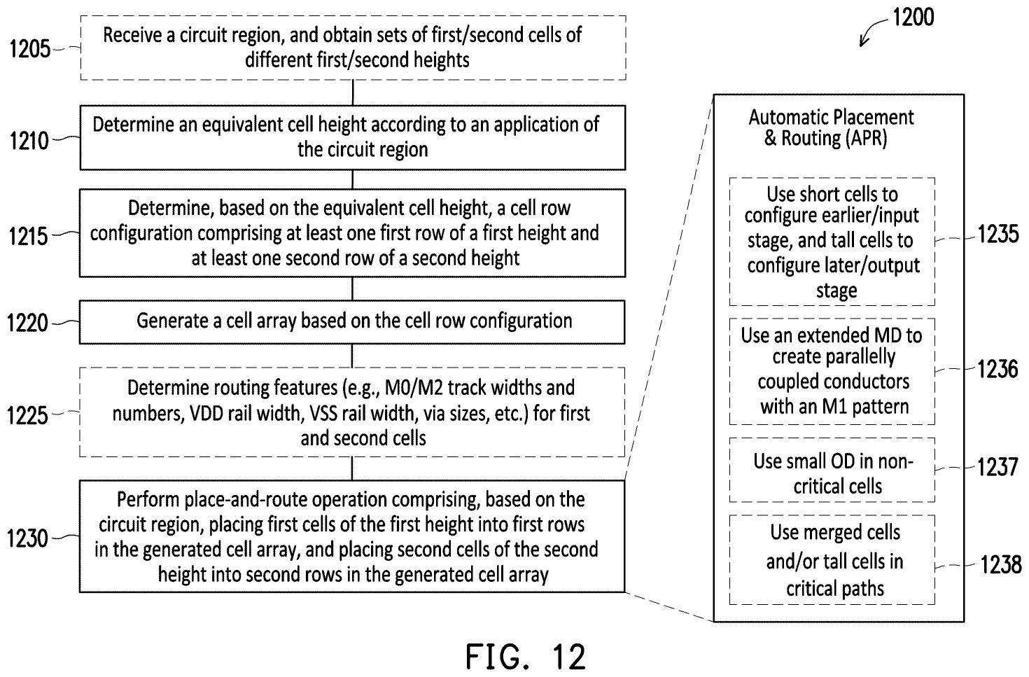

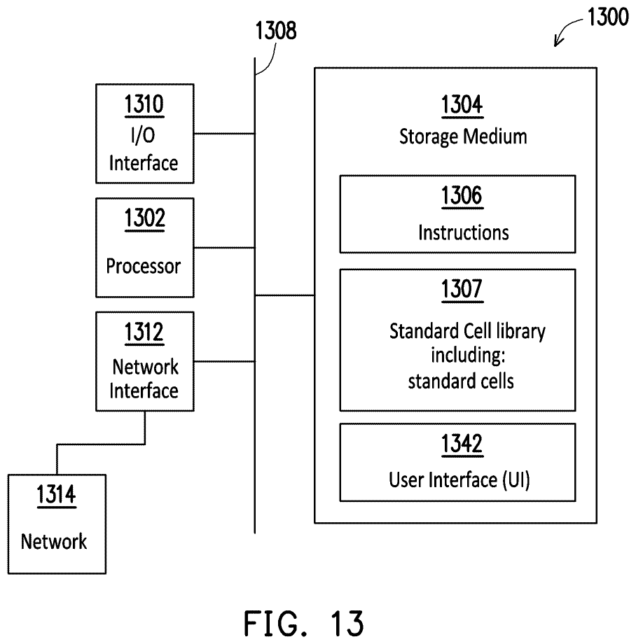

FIG. 12 is a flowchart of a method 1200 of generating an IC layout for a circuit region of an IC device, in accordance with some embodiments. In some embodiments, the method 1200 is an example of at least a part of the operation 1102. In at least one embodiment, the method 1200 is implementable at least in part using a processor, e.g., in an EDA system discussed below.

At operation 1205, the circuit region for which the IC layout is to be generated is received. In some embodiments, the circuit region comprises all circuitry of the IC device. In at least one embodiment, the circuit region comprises circuitry of a part of the IC device, and corresponds to one or more of the circuit regions described, for example, with respect to FIG. 5A. In some embodiments, the circuit region is received in the form of an IC schematic, i.e., an electrical diagram, of the circuit region. In some embodiments, the schematic is generated or provided in the form of a schematic netlist, such as a Simulation Program with Integrated Circuit Emphasis (SPICE) netlist. Other data formats, e.g., Verilog, for describing the design are usable in some embodiments.

In some embodiments, various sets of cells of different cell heights are obtained. For simplicity, first cells of a first cell height and second cells of a second cell heights are obtained. In an example, the first cells are tall cells and the second cells are short cells. In some embodiments, one more tall cells with different values of one or more of H_{T}, W_{T}, W_{SM}, and/or one more short cells with different values of one or more of H_{S}, W_{S}, W_{SM} are obtained from a cell library, as described with respect to FIG. 3. In at least one embodiment, at least one tall cell or short cell is derived, by the EDA system, from a default unit cell. For example, H and W of the default unit cell are used in conjunction with one or more of the relationships (1)-(6) and a predetermined set of design rules to generate tall cells and/or short cells that satisfy the set of design rules and are usable to achieve one or more PPA improvements, as described herein. In some embodiments, the whole or a part of operation 1205 is omitted.

At operation 1210, based on an application to be performed by the circuit region, an equivalent cell height, e.g., H_{E}, of the IC layout to be generated is determined. For example, as described herein, a look-up table prepared in advance is accessed. The look-up table associates a plurality of applications and/or circuit regions with different values of H_{E}. For example, a high speed application is associated with a high value of H_{E}, whereas a low power application is associated with a low value of H_{E}. The application of the circuit region is input into the look-up table which returns a value of H_{E} that matches, or is closest to, the input application.

At operation 1215, based on the determined equivalent cell height, a cell row configuration comprising at least one first row of a first height and at least one second row of a second height different from the first height. Example cell row configurations are described with respect to FIG. 2C. In at least one embodiment, various cell row configurations are developed in advance and associated with corresponding values of H_{E}, e.g., in a the same or a further look-up table into which the determined H_{E} is input and which returns a corresponding cell row configuration. In some embodiments, the determined H_{E} is used, together with H_{T} and H_{S} of the tall cells and short cells obtained at operation 1205, to calculate Rₘᵢₓ, based on the relationship (9). From the calculated Rₘᵢₓ and the relationship (8), it is possible to determine the number of tall rows and the number of short rows in the cell row configuration to be used. For example, when the calculated Rₘᵢₓ is 3, the cell row configuration 261 in FIG. 2C is to be used for generating the IC layout.

At operation 1220, a cell array is generated in accordance with the determined cell row configuration. For example, assuming that a cell row configuration comprising two short rows and two tall rows (2 Short 2 Tall) is determined to be used at operation 1215, the determined cell row configuration is repeatedly placed multiple times along the Y axis to cover a floorplan of the IC layout. A resulting cell array comprises a repeating pattern of 2 short rows, 2 tall rows, 2 short rows, 2 tall rows, etc. along the Y axis, as illustrated, e.g., in FIG. 5C. In at least one embodiment, at this stage, there are no cells placed yet in the generated cell array.

At operation 1225, one or more routing features are determined for cells to be placed in the generated cell array. Examples of routing features to be determined are described with respect to FIG. 10. In at least one embodiment, routing features are determined for each cell, based on the cell height, active region width, and/or various design rules. Routing feature for short cells and tall cells differ in various aspects, as described with respect to FIG. 10, to optimize one or more of PPA. In some embodiments, operation 1225 is omitted, and routing features are determined by an APR tool while performing an APR operation as described herein.

At operation 1230, a place-and-route operation is performed to generate the IC layout for the circuit region. In the place-and-route operation, one or more first cells of the first height are placed into one or more first rows of the first height in the generated cell array, and one or more second cells of the second height are placed into one or more second rows of the second height in the generated cell array. In at least one embodiment, the place-and-route operation comprises an APR operation performed by an APR tool or system. For example, based on the IC schematic of the circuit region, the APR tool place cells of various functions corresponding to the IC schematic into the generated cell array. When a cell of a specific function (e.g., AND gate) is to be placed in a tall row of the cell array, a tall cell having the specific function (i.e., AND gate) is placed. Similarly, when a cell of a specific function is to be placed in a short row of the cell array, a short cell having the specific function is placed.

Upon completion of the placement operation, a routing operation is performed to couple the placed cells in accordance with the IC schematic. In some embodiments, the routing operation is performed in accordance with the routing features determined at operation 1225. In at least one embodiment, the routing operation is performed based on other routing features and/or design rules.

During the APR operation, one or more of operations 1235-1238 is/are performed to achieve further PPA improvements, in accordance with some embodiments. In some embodiments, one or more of operations 1235-1238 is/are omitted.

At operation 1235, to configure a multi-stage circuit in the circuit region, one or more short cells are placed and routed to form an earlier or input stage, whereas tall cells are placed and routed to form a later or output stage, as described with respect to FIGS. 8A-8B. As a result, in one or more embodiments, it is possible to achieve low input impedance/capacitance and high driving current.

At operation 1236, for a cell with high OD density, e.g., a tall cell, where a source/drain of a P-type device is coupled to a source/drain of an N-type device by an M1 conductive pattern, an extended source/drain contact (MD) is used to form a parallel conductor with the M1 conductive pattern, as described with respect to FIGS. 7D-7F. As a result, in one or more embodiments, it is possible to reduce resistance and increase speed. In some embodiments, a required change for creating an extended MD in an existing layout of a cell is as simple as removing a cut-MD mask.

At operations 1237-1238, when a critical path is identified in the IC layout, it is possible in one or more embodiments to optimize at least one of critical cells along the critical path or non-critical cells outside the critical path. In at least one embodiment, to optimize critical cells along the critical path, cells configured for speed, such as merged cells, tall cells, are placed or created along the path to reduce the time delay and/or length of the path, as described with respect to FIG. 9A. In some embodiments, to optimize non-critical cells outside the critical path, cells configured for power and/or area, such as short cells, cells with small OD are placed to improve power and/or area, as described with respect to FIG. 9B.

After the place-and-route operation, the generated IC layout is subject to one or more verifications and/or simulations and/or modifications before manufacturing. In at least one embodiment, one or more advantages described herein are achievable by one or more IC layouts generated by the method 1200, and/or by IC devices manufactured based on such IC layouts.

The described methods include example operations, but they are not necessarily required to be performed in the order shown. Operations may be added, replaced, changed order, and/or eliminated as appropriate, in accordance with the spirit and scope of embodiments of the disclosure. Embodiments that combine different features and/or different embodiments are within the scope of the disclosure and will be apparent to those of ordinary skill in the art after reviewing this disclosure.

In some embodiments, at least one method(s) discussed above is performed in whole or in part by at least one EDA system. In some embodiments, an EDA system is usable as part of a design house of an IC manufacturing system discussed below.

FIG. 13 is a block diagram of an electronic design automation (EDA) system 1300 in accordance with some embodiments.

In some embodiments, EDA system 1300 includes an APR system. Methods described herein of designing layout diagrams represent wire routing arrangements, in accordance with one or more embodiments, are implementable, for example, using EDA system 1300, in accordance with some embodiments.

In some embodiments, EDA system 1300 is a general purpose computing device including a hardware processor 1302 and a non-transitory, computer-readable storage medium 1304. Storage medium 1304, amongst other things, is encoded with, i.e., stores, computer program code 1306, i.e., a set of executable instructions. Execution of instructions 1306 by hardware processor 1302 represents (at least in part) an EDA tool which implements a portion or all of the methods described herein in accordance with one or more embodiments (hereinafter, the noted processes and/or methods).

Processor 1302 is electrically coupled to computer-readable storage medium 1304 via a bus 1308. Processor 1302 is also electrically coupled to an I/O interface 1310 by bus 1308. A network interface 1312 is also electrically connected to processor 1302 via bus 1308. Network interface 1312 is connected to a network 1314, so that processor 1302 and computer-readable storage medium 1304 are capable of connecting to external elements via network 1314. Processor 1302 is configured to execute computer program code 1306 encoded in computer-readable storage medium 1304 in order to cause system 1300 to be usable for performing a portion or all of the noted processes and/or methods. In one or more embodiments, processor 1302 is a central processing unit (CPU), a multi-processor, a distributed processing system, an application specific integrated circuit (ASIC), and/or a suitable processing unit.

In one or more embodiments, computer-readable storage medium 1304 is an electronic, magnetic, optical, electromagnetic, infrared, and/or a semiconductor system (or apparatus or device). For example, computer-readable storage medium 1304 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 1304 includes a compact disk-read only memory (CD-ROM), a compact disk-read/write (CD-R/W), and/or a digital video disc (DVD).

In one or more embodiments, storage medium 1304 stores computer program code 1306 configured to cause system 1300 (where such execution represents (at least in part) the EDA tool) to be usable for performing a portion or all of the noted processes and/or methods. In one or more embodiments, storage medium 1304 also stores information which facilitates performing a portion or all of the noted processes and/or methods. In one or more embodiments, storage medium 1304 stores library 1307 of standard cells including such standard cells as disclosed herein.

EDA system 1300 includes I/O interface 1310. I/O interface 1310 is coupled to external circuitry. In one or more embodiments, I/O interface 1310 includes a keyboard, keypad, mouse, trackball, trackpad, touchscreen, and/or cursor direction keys for communicating information and commands to processor 1302.

EDA system 1300 also includes network interface 1312 coupled to processor 1302. Network interface 1312 allows system 1300 to communicate with network 1314, to which one or more other computer systems are connected. Network interface 1312 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 1300.

System 1300 is configured to receive information through I/O interface 1310. The information received through I/O interface 1310 includes one or more of instructions, data, design rules, libraries of standard cells, and/or other parameters for processing by processor 1302. The information is transferred to processor 1302 via bus 1308. EDA system 1300 is configured to receive information related to a UI through I/O interface 1310. The information is stored in computer-readable storage medium 1304 as user interface (UI) 1342.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1300. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

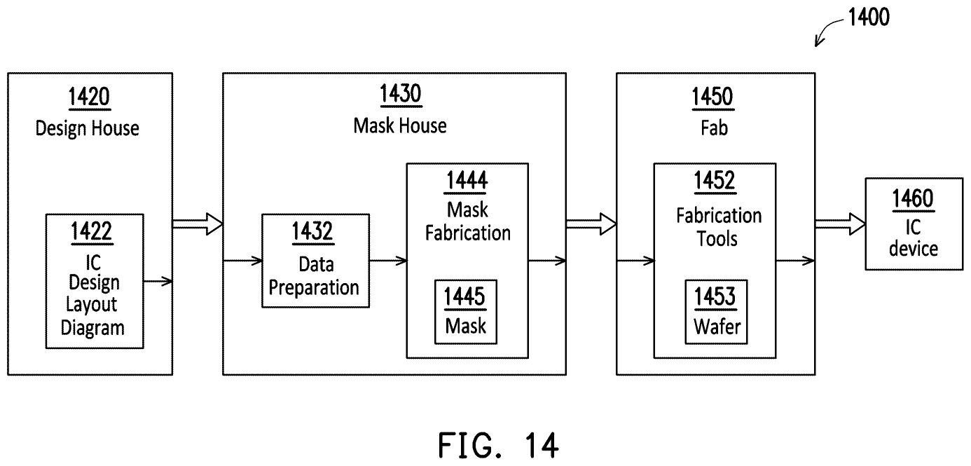

FIG. 14 is a block diagram of an integrated circuit (IC) manufacturing system 1400, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 1400.

In FIG. 14, IC manufacturing system 1400 includes entities, such as a design house 1420, a mask house 1430, and an IC manufacturer/fabricator (“fab”) 1450, that interact with one another in the design, development, and manufacturing cycles and/or services related to manufacturing an IC device 1460. The entities in system 1400 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1420, mask house 1430, and IC fab 1450 is owned by a single larger company. In some embodiments, two or more of design house 1420, mask house 1430, and IC fab 1450 coexist in a common facility and use common resources.

Design house (or design team) 1420 generates an IC design layout diagram 1422. IC design layout diagram 1422 includes various geometrical patterns designed for an IC device 1460. The geometrical patterns correspond to patterns of metal, oxide, or semiconductor layers that make up the various components of IC device 1460 to be fabricated. The various layers combine to form various IC features. For example, a portion of IC design layout diagram 1422 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1420 implements a proper design procedure to form IC design layout diagram 1422. The design procedure includes one or more of logic design, physical design or place-and-route operation. IC design layout diagram 1422 is presented in one or more data files having information of the geometrical patterns. For example, IC design layout diagram 1422 can be expressed in a GDSII file format or DFII file format.

Mask house 1430 includes data preparation 1432 and mask fabrication 1444. Mask house 1430 uses IC design layout diagram 1422 to manufacture one or more masks 1445 to be used for fabricating the various layers of IC device 1460 according to IC design layout diagram 1422. Mask house 1430 performs mask data preparation 1432, where IC design layout diagram 1422 is translated into a representative data file (“RDF”). Mask data preparation 1432 provides the RDF to mask fabrication 1444. Mask fabrication 1444 includes a mask writer. A mask writer converts the RDF to an image on a substrate, such as a mask (reticle) 1445 or a semiconductor wafer 1453. The design layout diagram 1422 is manipulated by mask data preparation 1432 to comply with particular characteristics of the mask writer and/or requirements of IC fab 1450. In FIG. 14, mask data preparation 1432 and mask fabrication 1444 are illustrated as separate elements. In some embodiments, mask data preparation 1432 and mask fabrication 1444 can be collectively referred to as mask data preparation.

In some embodiments, mask data preparation 1432 includes optical proximity correction (OPC) which uses lithography enhancement techniques to compensate for image errors, such as those that can arise from diffraction, interference, other process effects and the like. OPC adjusts IC design layout diagram 1422. In some embodiments, mask data preparation 1432 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1432 includes a mask rule checker (MRC) that checks the IC design layout diagram 1422 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1422 to compensate for limitations during mask fabrication 1444, which may undo part of the modifications performed by OPC in order to meet mask creation rules.

In some embodiments, mask data preparation 1432 includes lithography process checking (LPC) that simulates processing that will be implemented by IC fab 1450 to fabricate IC device 1460. LPC simulates this processing based on IC design layout diagram 1422 to create a simulated manufactured device, such as IC device 1460. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1422.

It should be understood that the above description of mask data preparation 1432 has been simplified for the purposes of clarity. In some embodiments, data preparation 1432 includes additional features such as a logic operation (LOP) to modify the IC design layout diagram 1422 according to manufacturing rules. Additionally, the processes applied to IC design layout diagram 1422 during data preparation 1432 may be executed in a variety of different orders.

After mask data preparation 1432 and during mask fabrication 1444, a mask 1445 or a group of masks 1445 are fabricated based on the modified IC design layout diagram 1422. In some embodiments, mask fabrication 1444 includes performing one or more lithographic exposures based on IC design layout diagram 1422. In some embodiments, an electron-beam (e-beam) or a mechanism of multiple e-beams is used to form a pattern on a mask (photomask or reticle) 1445 based on the modified IC design layout diagram 1422. Mask 1445 can be formed in various technologies. In some embodiments, mask 1445 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1445 includes a transparent substrate (e.g., fused quartz) and an opaque material (e.g., chromium) coated in the opaque regions of the binary mask. In another example, mask 1445 is formed using a phase shift technology. In a phase shift mask (PSM) version of mask 1445, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1444 is used in a variety of processes. For example, such a mask(s) is used in an ion implantation process to form various doped regions in semiconductor wafer 1453, in an etching process to form various etching regions in semiconductor wafer 1453, and/or in other suitable processes.

IC fab 1450 is an IC fabrication business that includes one or more manufacturing facilities for the fabrication of a variety of different IC products. In some embodiments, IC Fab 1450 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1450 includes fabrication tools 1452 configured to execute various manufacturing operations on semiconductor wafer 1453 such that IC device 1460 is fabricated in accordance with the mask(s), e.g., mask 1445. In various embodiments, fabrication tools 1452 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1450 uses mask(s) 1445 fabricated by mask house 1430 to fabricate IC device 1460. Thus, IC fab 1450 at least indirectly uses IC design layout diagram 1422 to fabricate IC device 1460. In some embodiments, semiconductor wafer 1453 is fabricated by IC fab 1450 using mask(s) 1445 to form IC device 1460. In some embodiments, the IC fabrication includes performing one or more lithographic exposures based at least indirectly on IC design layout diagram 1422. Semiconductor wafer 1453 includes a silicon substrate or other proper substrate having material layers formed thereon. Semiconductor wafer 1453 further includes one or more of various doped regions, dielectric features, multilevel interconnects, and the like (formed at subsequent manufacturing steps).

In some embodiments, an integrated circuit (IC) device comprises a plurality of rows of semiconductor devices. The plurality of rows is elongated along a first axis and arranged side-by-side along a second axis transverse to the first axis. The plurality of rows comprises a plurality of first rows having a first height along the second axis, and a plurality of second rows having a second height along the second axis. The second height is smaller than the first height. Each of the plurality of rows comprises a first active region of a first conductivity type, and a second active region of a second conductivity type different from the first conductivity type. The second active region is spaced from the first active region along the second axis. In one or more of the plurality of first rows, the first active region or the second active region comprises: a portion having a first width along the second axis, and a further portion having a reduced first width smaller than the first width along the second axis. Alternatively or additionally, in one or more of the plurality of second rows, the first active region or the second active region comprises: a portion having a second width along the second axis, and a further portion having a reduced second width smaller than the second width along the second axis.

In some embodiments, an integrated circuit (IC) layout is stored on a non-transitory computer-readable storage medium. The IC layout comprises a plurality of cells having a same cell height along a cell height direction. Each cell of the plurality of cells comprises a first active region of a first conductivity type, and a second active region of a second conductivity type different from the first conductivity type. The second active region is spaced from the first active region along the cell height direction. The first active region or the second active region of a first cell among the plurality of cells has a first width along the cell height direction. The first active region or the second active region of a second cell among the plurality of cells has a second width along the cell height direction. The second width is smaller than the first width.

In some embodiments, a method of generating an integrated circuit (IC) layout for a circuit region is performed at least partially by a processor. The method comprises generating a cell array comprising a plurality of first rows each having a first height along a cell height direction, and a plurality of second rows each having a second height along the cell height direction. The second height is greater than the first height. The method further comprises performing a place-and-route operation to generate the IC layout for the circuit region. The place-and-route operation comprises, based on the circuit region, placing one or more first cells of the first height into one or more first rows of the first height in the generated cell array, and placing one or more second cells of the second height into one or more second rows of the second height in the generated cell array. The method further comprises storing the generated IC layout in a non-transitory, computer-readable storage medium. The circuit region comprises an input stage and an output stage electrically coupled to the input stage. The place-and-route operation comprises configuring the input stage by at least one first cell among the one or more first cells of the first height, and configuring the output stage by at least one second cell among the one or more second cells of the second height greater than the first height.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
a plurality of rows of semiconductor devices, the plurality of rows elongated along a first axis and arranged side-by-side along a second axis transverse to the first axis,
wherein
the plurality of rows comprises:
a plurality of first rows each having a first height along the second axis, and
a plurality of second rows each having a second height along the second axis, the second height smaller than the first height,
each of the plurality of rows comprises:
a first active region of a first conductivity type, and
a second active region of a second conductivity type different from the first conductivity type, the second active region spaced from the first active region along the second axis, and
at least one of:
in one or more of the plurality of first rows, the first active region or the second active region comprises:
a portion having a first width along the second axis, and
a further portion having a reduced first width along the second axis, the reduced first width smaller than the first width, or
in one or more of the plurality of second rows, the first active region or the second active region comprises:
a portion having a second width along the second axis, and
a further portion having a reduced second width along the second axis, the reduced second width smaller than the second width.

2. The IC device of claim 1, wherein
the second width is smaller than the first width.

3. The IC device of claim 1, wherein
the semiconductor devices comprise gate-all-around (GAA) devices.

4. The IC device of claim 1, wherein
the plurality of rows comprises, along the second axis, a repeating pattern of a set of rows, and
the set of rows comprises at least one of the plurality of first rows and at least one of the plurality of second rows.

5. The IC device of claim 1, wherein
the plurality of rows further comprises a third row,
the first active region of the third row is merged with the first active region of one first row among the plurality of first rows, or with the first active region of one second row among the plurality of second rows, into a merged first active region, and
the merged first active region is arranged, along the second axis, between the second active region of the third row and the second active region of said one first row or said one second row.

6. The IC device of claim 5, wherein at least one of:
the third row is a further first row among the plurality of first rows and the first active region of the third row is merged with the first active region of said one first row,
the third row is a further first row among the plurality of first rows and the first active region of the third row is merged with the first active region of said one second row, or
the third row is a further second row among the plurality of second rows and the first active region of the third row is merged with the first active region of said one second row.

7. An integrated circuit (IC) layout stored on a non-transitory computer-readable storage medium, the IC layout comprising:
a plurality of cells having a same cell height along a cell height direction,
wherein
each cell of the plurality of cells comprises
a first active region of a first conductivity type, and
a second active region of a second conductivity type different from the first conductivity type, the second active region spaced from the first active region along the cell height direction,
the first active region or the second active region of a first cell among the plurality of cells has a first width along the cell height direction, and
the first active region or the second active region of a second cell among the plurality of cells has a second width along the cell height direction, the second width smaller than the first width.

8. The IC layout of claim 7, wherein
the first cell and the second cell are in a same row of cells, the row extending along a direction transverse to the cell height direction.

9. The IC layout of claim 7, further comprising:
a third cell, wherein
the first active region of the third cell is merged with the first active region of another cell among the plurality of cells into a merged first active region, and
the merged first active region is arranged, along the cell height direction, between the second active region of the third cell and the second active region of said another cell.

10. A method of generating an integrated circuit (IC) layout for a circuit region, the method performed at least partially by a processor and comprising:
generating a cell array comprising:
a plurality of first rows each having a first height along a cell height direction, and
a plurality of second rows each having a second height along the cell height direction, the second height greater than the first height;
performing a place-and-route operation to generate the IC layout for the circuit region, the place-and-route operation comprising, based on the circuit region,
placing one or more first cells of the first height into one or more first rows of the first height in the generated cell array, and
placing one or more second cells of the second height into one or more second rows of the second height in the generated cell array; and
storing the generated IC layout in a non-transitory, computer-readable storage medium,
wherein
the circuit region comprises an input stage and an output stage electrically coupled to the input stage, and
the place-and-route operation comprises:
configuring the input stage by at least one first cell among the one or more first cells of the first height, and
configuring the output stage by at least one second cell among the one or more second cells of the second height greater than the first height.

11. The method of claim 10, wherein the IC layout comprises at least one of:
an active region of at least one first cell of the first height having a smaller active region width than an active region of at least one further first cell of the first height, or
an active region of at least one second cell of the second height having a smaller active region width than an active region of at least one further second cell of the second height.

12. The method of claim 10, wherein
a first cell among the one or more first cells differs from a second cell among the one or more second cells in at least one of:
a number of first metal tracks of a first metal layer closest to active regions,
a width of a first metal track of the first metal layer,
a width of a first power rail for a first power supply voltage in the first metal layer,
a width of a second power rail for a second power supply voltage in the first metal layer, the second power supply voltage different from the first power supply voltage,
a number of second metal tracks of a second metal layer, the second metal layer immediately over a third metal layer which is immediately over the first metal layer,
a width of a second metal track of the second metal layer,
a size of a first via structure in a first via layer between the first metal layer and the third metal layer, or
a size of a second via structure in a second via layer between the second metal layer and the third metal layer.

13. The method of claim 12, wherein
at least one of the first cell or the second cell comprises at least one of
the width of the first power rail different from the width of the second power rail,
different first metal tracks having different widths, or
different second metal tracks having different widths.

14. The method of claim 12, wherein
the first cell comprises at least one of:
the width of the first power rail different from the width of the second power rail,
end second metal tracks correspondingly overlapping the first power rail and the second power rail having different widths, or
the width of a second metal track between the end second metal tracks smaller than the widths of the end second metal tracks.

15. The method of claim 12, wherein
the second cell comprises at least one of:
the width of the first power rail different from the width of the second power rail,
a first set of first metal tracks having greater widths than a second set of first metal tracks arranged alternatingly with the first set of first metal tracks,
a middle first metal track in the first set having a width smaller than other first metal tracks in the first set, or
the second metal tracks having the same width.

16. The method of claim 10, wherein
the place-and-route operation further comprises:
merging neighboring cells abutting each other along the cell height direction into a merged cell, so that a first active region of one of the neighboring cells is merged with a second active region of the other of the neighboring cells into a merged active region of the merged cell, the merged active region having an active region width greater than active region widths of the first and second active regions before said merging.

17. The method of claim 16, wherein
the neighboring cells before said merging and the merged cell obtained by said merging are arranged along a critical path of the circuit region, the critical path having a time delay greater than a timing requirement.

18. The method of claim 17, wherein
the neighboring cells before said merging comprise:
a first cell of the first height and a second cell of the second height,
a pair of first cells of the first height, or
a pair of second cells of the second height.

19. The method of claim 17, wherein
the place-and-route operation further comprises:
routing the critical path through one or more merged cells and one or more second cells of the second height.

20. The method of claim 19, wherein
the place-and-route operation further comprises:
routing a non-critical path through one or more first cells of the first height, a non-critical path having a time delay not greater than the timing requirement.
